(19) United States
(12) Patent Application Publication
(10) Pub. No.: US 2017/0229417 A1
(43) Pub. Date: Aug. 10, 2017

(54) MOUNTING SUBSTRATE MANUFACTURING APPARATUS AND METHOD OF MANUFACTURING MOUNTING SUBSTRATE

(71) Applicant: Sharp Kabushiki Kaisha, Sakai City, Osaka (JP)

(72) Inventors: Katsuhiro YAMAGUCHI, Sakai City (JP); Nobuhiro NAKATA, Sakai City (JP)

(21) Appl. No.: 15/502,585

(22) PCT Filed: Aug. 17, 2015
(86) PCT No.: PCT/JP2015/073008

§ 371 Date: Feb. 8, 2017

(30) Foreign Application Priority Data
Aug. 22, 2014 (JP) 2014-169428

(51) Int. Cl. H01L 23/00; G02F 1/13; G02F 1/1345; H05K 3/32

(52) U.S. Cl. CPC H01L 24/75; H05K 3/32; G02F 1/1303; G02F 1/13452; H01L 24/29; H01L 24/73; H01L 24/16; H01L 24/32; H01L 24/83; H05K 2203/1105; H05K 2203/0278; H01L 2224/293; H01L 2224/2929; G02F 2201/54; H01L 2224/73204; H01L 2224/16227; H01L 2224/32227; H01L 2224/75252; H01L 2224/75251; H01L 2224/75301; H01L 2224/83203; H01L 2224/83851; H01L 2224/83862

(57) ABSTRACT

A driver mounting apparatus 40 includes a driver mount-side heat supply support member 42, a substrate support member 41, a driver-side heat supply support member 43, a first moving portion 44, and a second moving portion 45. The driver mount-side heat supply support member 42 supports a driver mount portion GSd and supplies heat to the driver mount portion GSd. The substrate support member supports a substrate main portion GSm. The driver-side heat supply support member 43 supports and sandwich a driver 21 with the driver mount-side heat supply support member 42 and supplies heat to the driver 21. The first moving portion 44 relatively moves the driver mount portion GSd and the driver mount-side heat supply support member 42 in an overlapping direction in which the glass substrate GS and the driver 21 are overlapped. The second moving portion 45 relatively moves the driver 21 and the driver-side heat supply support member 43 in the overlapping direction.

### TECHNICAL FIELD

The present invention relates to a mounting substrate manufacturing apparatus and a method of manufacturing mounting substrate.

### BACKGROUND ART

In portable electronic devices including cell phones, smartphones, and notebook computers, display devices including display panels such as liquid crystal panels are used. Each of such display devices includes a display panel and a semiconductor chip. The display panel includes a display area for displaying images. The semiconductor chip is for processing input signals from a signal source and generating output signals. The semiconductor chip then sends the output signals to the display area to drive the display panel. In general, it is preferable to use a chip on glass (COG) mounting technology for mounting the semiconductor chip directly in an area of the display panel outside the display area in the display device that is classified as a small sized or a small to middle sized panel. An example of a manufacturing apparatus for manufacturing such kind of the display device disclosed in Patent Document 1 has been known.

Patent Document 1 discloses the manufacturing apparatus including a guide plate disposed on a portion of a stage on which a substrate of the display panel is placed. The guide plate includes an upper surface that is a rough surface with 0.1 μm to 5 μm roughness. According to the configuration, an area of the bottom surface of the substrate contacting the guide plate is reduced and thus heat from a head disposed on an opposite side from the stage with respect to the substrate is less likely to be transmitted to the guide plate. Therefore, the mounting of the semiconductor chip completes in short time.

### RELATED ART DOCUMENT

### Patent Document

Patent Document 1: Japanese Unexamined Patent Application Publication No. 2003-249532

### Problem to be Solved by the Invention

However, undulation may be caused on a surface of the substrate due to the manufacturing process and a thickness of the substrate may be uneven within a surface plane. With such a configuration, the head may apply pressure and heat to the semiconductor chip at various timings. As a result, the terminals of the semiconductor chip may not be connected correctly and mounting errors may be caused. If the board and the semiconductor chip are reduced in thickness, warpage is likely to be caused in the board and the semiconductor chip due to the difference between the expansion/shrinkage amount of the substrate and that of the semiconductor chip. Such difference is caused by the heat applied during the mounting process.

### DISCLOSURE OF THE PRESENT INVENTION

The technology disclosed in this description was made in view of the above circumstances. An object is to provide technology that mounting errors are less likely to be caused and warpage is less likely to be caused.

### Means for Solving the Problem

Amounting substrate manufacturing apparatus according to the present invention includes a component mount-side heat supply support member arranged on an opposite side from a component with respect to a substrate where the component is to be mounted, the component mount-side heat supply support member supporting a component mount portion of the substrate where the component is to be mounted and suppling heat to the component mount portion, a substrate support member arranged on a same side with the component mount-side heat supply support member with respect to the substrate and supporting a substrate main portion of the substrate except for the component mount portion, a component-side heat supply support member arranged on an opposite side from the component mount portion with respect to the component, the component-side heat supply support member sandwiching and supporting the component with the component mount-side heat supply support member supporting the component mount portion and supplies heat to the component, a first moving portion that relatively moves the component mount portion and the component mount-side heat supply support member in an overlapping direction in which the substrate and the component are overlapped, and a second moving portion that relatively moves the component and the component-side heat supply support member in the overlapping direction.

The component is mounted on the substrate as follows. The substrate main portion of the substrate except for the component mount portion is supported by the substrate support member that is arranged on an opposite side from the component with respect to the substrate. The component mount portion and the component mount-side heat supply support member, which is arranged on the opposite side from the component with respect to the substrate, are moved relatively closer to each other by the first moving portion in the overlapping direction in which the substrate and the component are overlapped. Further, the component and the component-side heat supply support member, which is arranged on the opposite side from the component mount portion with respect to the component, are moved relatively closer to each other by the second moving portion in the overlapping direction. The component-side heat supply support member and the component mount-side heat supply support member sandwich the component and the component mount portion therebetween and press the component and the component mount portion. The component mount-side heat supply support member supplies heat to the component mount portion and the component-side heat supply support member supplies heat to the component. Thus, the component is mounted on the substrate.

Thus, the component mount-side heat supply support member and the component-side heat supply support member are relatively movable by the first moving portion and the second moving portion, respectively. Therefore, the timing of contacting the component mount-side heat supply support member with the component mount portion and starting heat supply and the timing of contacting the component-side heat supply support member with the component and starting heat supply are freely determined. Therefore, even if the thickness of the component mount portion of the substrate and the thickness of the component may vary due to the manufacturing matters, unevenness in heating and pressing caused due to the variation of the thicknesses is less likely to be caused and connection errors are less likely to occur by adjusting the timings of starting heat supply by the first moving portion and the second moving portion. Further, even if difference in the thermal conductivity is caused due to the difference in the material of the component and the substrate, the difference between the thermal expansion/shrinkage amounts of the substrate and the component having different thermal conductivity is reduced by adjusting the timings of starting heat supply by the first moving portion and the second moving portion. Accordingly, warpage that may be caused by mounting of the component is less likely to occur with the substrate and the component being thinned. Further, if the positions of the substrate support member and the component mount-side heat supply support member are fixed in the overlapping direction, the component mount-side heat supply support member continues supplying heat to the component mount portion until the component-side heat supply support member starts pressing of the component and therefore, connection errors may occur. However, such errors are obviated by adjusting the timings of starting heat supply by the first moving portion and the second moving portion.

Preferable embodiments of the mounting substrate manufacturing apparatus may include the following configurations.

(1) The mounting substrate manufacturing apparatus may further include a movement control portion configured to control the first moving portion and the second moving portion to adjust relative moving speed of the component mount portion and the component mount-side heat supply support member and relative moving speed of the component and the component-side heat supply support member, respectively. Accordingly, the movement control portion controls the first moving portion and the second moving portion to control relative moving speed of the component mount portion relative to the component mount-side heat supply support member and control relative moving speed of the component-side heat supply support member relative to the component to set appropriate timing of starting heat supply to the component mount portion and the component. Comparing to the configuration that the relative moving speed is fixed and the position of the component mount portion and the component mount-side heat supply support member and the position of the component and the component-side heat supply support member are adjusted, respectively, the configuration of the manufacturing apparatus is less likely to be complicated and the manufacturing apparatus is effectively reduced in size.

(2) The movement control portion may be configured to control the first moving portion and the second moving portion such that timing of contacting the component mount-side heat supply support member with the component mount portion and timing of contacting the component-side heat supply support member with the component are same. Accordingly, for example, if the substrate having thermal conductivity lower than that of the component is thinner than the component, the thermal expansion/contraction amounts of the substrate and the component are effectively equalized.

(3) The movement control portion may be configured to control the first moving portion and the second moving portion such that timing of contacting the component mount-side heat supply support member with the component mount portion is prior to timing of contacting the component-side heat supply support member with the component. Accordingly, for example, if the substrate having thermal conductivity lower than that of the component has substantially same thickness as that of the component or greater thickness than the component, the thermal expansion/contraction amounts of the substrate and the component are effectively equalized.

(4) The mounting substrate manufacturing apparatus may further include a timer counting time that has passed after the component mount-side heat supply support member is in contact with the component mount portion. The movement control portion may be configured to control the second moving portion to start relative movement of the component and the component-side heat supply support member to be closer to each other, if counted time counted by the timer reaches predetermined time. Accordingly, when the component mount-side heat supply support member is first in contact with the component mount portion and supplies heat thereto, the timer counts time that has passed after the contact of the component mount-side heat supply support member and the component mount portion. The relative movement of the component and the component-side heat supply support member to be closer to each other is started by the second moving portion if the counted time reaches the predetermined time. The component-side heat supply support member starts to supply heat to the component after a certain amount of heat is supplied from the component mount-side heat supply support member to the component mount portion. Therefore, the thermal expansion/contraction amounts of the substrate and the component are effectively equalized.

(5) The movement control portion may be configured to control the first moving portion and the second moving portion such that timing of contacting the component mount-side heat supply support member with the component mount portion is after timing of contacting the component-side heat supply support member with the component. Accordingly, for example, if the substrate having thermal conductivity lower than that of the component is thinner than the component and the thickness difference is quite large, the thermal expansion/contraction amounts of the substrate and the component are effectively equalized.

(6) The movement control portion may be configured to control the first moving portion and the second moving portion such that relative moving speed of the component mount portion and the component mount-side heat supply support member and relative moving speed of the component and the component-side heat supply support member change during moving. Accordingly, the timings described below are determined appropriately according to the position of the component mount portion and the component mount-side heat supply support member and the position of the component and the component-side heat supply support member. The timings include the timing of contacting the component mount-side heat supply support member with the component mount portion and the timing of contacting the component-side heat supply support member with the component. Further, for example, the relative moving speed is set fast for a while from the starting of the mounting and set slow from the intermediate timing to the end such that shock that may be caused when the component-side heat supply support member is contacted with the component and when the component mount-side heat supply support member is contacted with the component mount portion may be reduced.

(7) The component mount-side heat supply support member may be fixed with respect to the overlapping direction. The first moving portion may be configured to move the substrate support member such that the component mount portion of the substrate supported by the substrate support member is relatively moved with respect to the component mount-side heat supply support member. The second moving portion may be configured to move the component-side heat supply support member such that the component-side heat supply support member is relatively moved with respect to the component. The substrate includes the component mount portion and the substrate main portion that is supported by the substrate support member, and the component mount portion is relatively moved to be closer to the component mount-side heat supply support member that is fixed in the overlapping direction, as the first moving portion moves the substrate support member. The component-side heat supply support member is relatively moved to be closer to the component as being moved by the second moving portion. Thus, the position of the component mount-side heat supply support member is fixed in the overlapping direction as is in the previous apparatus. Therefore, a cost for changing the configuration of the previous manufacturing apparatus is maintained low.

A method of manufacturing a mounting substrate according to the present invention includes a provisional pressing process in which a component is provisionally pressed and fixed on a substrate, and a pressing process. In the pressing process, following operations are executed. A substrate main portion of the substrate except for a component mount portion where the component is to be mounted is supported by a substrate support member arranged on an opposite side from the component with respect to the substrate where the component is to be mounted. A component mount-side heat supply support member and a component mount portion that are arranged on a same side with the substrate support member with respect to the substrate are relatively moved by a first moving portion in an overlapping direction in which the substrate and the component are overlapped. A component-side heat supply support member and the component that are arranged on an opposite side from the component mount-side supply support member with respect to the substrate are relatively moved by a second moving portion in the overlapping direction. The component mount portion is in contact with and supported by the component mount-side heat supply support member and heat is supplied to the component mount portion from the component mount-side heat supply support member. The component is in contact with and supported by the component-side heat supply support member and heat is supplied to the component from the component-side heat supply support member, whereby the component is pressed and fixed on the substrate.

The component that is provisionally pressed and mounted on the substrate in the provisional pressing process is mounted on the substrate as follows. The substrate main portion of the substrate except for the component mount portion is supported by the substrate support member that is arranged on the opposite side from the component with respect to the substrate. The component mount portion and the component mount-side heat supply support member that is arranged on the opposite side from the component with respect to the substrate is relatively moved to be closer to each other by the first moving portion in the overlapping direction in which the substrate and the component are overlapped. The component and the component-side heat supply support member that is arranged on the opposite side from the component amount portion with respect to the component are relatively moved to be closer to each other by the second moving portion in the overlapping direction. The component-side heat supply support member and the component mount-side heat supply support member sandwich the component and the component mount portion therebetween and press them. The component mount-side heat supply support member supplies heat to the component mount portion with pressing and the component-side heat supply support member supplies heat to the component with pressing. Thus, the component is mounted on the substrate.

Thus, the component mount-side heat supply support member and the component-side heat supply support member are relatively movable by the first moving portion and the second moving portion, respectively. Therefore, the timing of contacting the component mount-side heat supply support member with the component mount portion and starting heat supply and the timing of contacting the component-side heat supply support member with the component and starting heat supply are freely determined. Therefore, even if the thickness of the component mount portion of the substrate and the thickness of the component may vary due to the manufacturing matters, unevenness in heating and pressing caused due to the variation of the thicknesses is less likely to be caused and connection errors are less likely to occur by adjusting the timings of starting heat supply by the first moving portion and the second moving portion. Further, even if difference in the thermal conductivity is caused due to the difference in the material of the component and the substrate, the difference between the thermal expansion/shrinkage amounts of the substrate and the component having different thermal conductivity is reduced by adjusting the timings of starting heat supply by the first moving portion and the second moving portion. Accordingly, warpage that may be caused by mounting of the component is less likely to occur with the substrate and the component being thinned. Further, if the positions of the substrate support member and the component mount-side heat supply support member are fixed in the overlapping direction, the component mount-side heat supply support member continues supplying heat to the component mount portion until the component-side heat supply support member 43 starts pressing of the component and therefore, connection errors may occur. However, such errors are obviated by adjusting the timings of starting heat supply by the first moving portion and the second moving portion. Thus, the connection errors are less likely to occur and warpage is less likely to be caused.

Preferable embodiments of the method of manufacturing a mounting substrate may include the following configurations.

(1) In the pressing process, a movement control portion may control the first moving portion and the second moving portion to adjust relative moving speed of the component mount portion and the component mount-side heat supply support member and adjust relative moving speed of the component and the component-side heat supply support member, respectively. Accordingly, the movement control portion controls the first moving portion and the second moving portion to control relative moving speed of the component mount portion relative to the component mount-side heat supply support member and control relative moving speed of the component-side heat supply support member relative to the component to set appropriate timing of starting heat supply to the component mount portion and the component. Comparing to the configuration that the relative moving speed is fixed and the position of the component mount portion and the component mount-side heat supply support member and the position of the component and the component-side heat supply support member are adjusted, respectively, the configuration of the manufacturing apparatus is less likely to be complicated and the manufacturing apparatus is effectively reduced in size.

(2) In the pressing process, the movement control portion may control the first moving portion and the second moving portion such that timing of contacting the component mount-side heat supply support member with the component mount portion and timing of contacting the component-side heat supply support member with the component are same. Accordingly, for example, if the substrate having thermal conductivity lower than that of the component is thinner than the component, the thermal expansion/contraction amounts of the substrate and the component are effectively equalized.

(3) In the pressing process, the movement control portion may control the first moving portion and the second moving portion such that timing of contacting the component mount-side heat supply support member with the component mount portion is prior to timing of contacting the component-side heat supply support member with the component. Accordingly, for example, if the substrate having thermal conductivity lower than that of the component has substantially same thickness as that of the component or has greater thickness than the component, the thermal expansion/contraction amounts of the substrate and the component are effectively equalized.

(4) In the pressing process, the movement control portion may control the first moving portion and the second moving portion such that timing of contacting the component mount-side heat supply support member with the component mount portion is after timing of contacting the component-side heat supply support member with the component. Accordingly, for example, if the substrate having thermal conductivity lower than that of the component is thinner than the component and the thickness difference is quite large, the thermal expansion/contraction amounts of the substrate and the component are effectively equalized.

### Advantageous Effect of the Invention

According to the present invention, mounting errors are less likely to be caused and warpage is less likely to be caused.

### BRIEF DESCRIPTION OF THE DRAWINGS

FIG. 1 is a schematic plan view illustrating a connection configuration of a liquid crystal panel where a driver is mounted, a flexible printed circuit board, and a control circuit board.

FIG. 2 is a schematic cross-sectional view illustrating a cross-sectional configuration of a liquid crystal display device taken along a long side.

FIG. 3 is a schematic cross-sectional view illustrating a cross-sectional configuration of the liquid crystal panel.

FIG. 4 is an enlarged plan view illustrating a mounting area of an array board of the liquid crystal panel, the driver and the flexible printed circuit board being mounted in the mounting area.

FIG. 5 is a cross-sectional view taken along line A-A in FIG. 4.

FIG. 6 is a cross-sectional view taken along line B-B in FIG. 4.

FIG. 7 is a cross-sectional view of the driver mounting apparatus taken along line A-A in FIG. 4 and illustrating an operation of a substrate support member and a driver-side heat supply support member since an initial state.

FIG. 8 is a cross-sectional view of the driver mounting apparatus taken along line B-B in FIG. 4 and illustrating an operation of the substrate support member and the driver-side heat supply support member since an initial state.

FIG. 9 is a block diagram illustrating an electrical configuration of the driver mounting apparatus.

FIG. 10 is a cross-sectional view of the driver mounting apparatus taken along line A-A in FIG. 4 and illustrating that a driver mount-side heat supply support member and the driver-side heat supply support member are simultaneously in contact with a driver mount portion and the driver, respectively, if a thickness of the driver mount portion is a designed value.

FIG. 11 is a cross-sectional view of the driver mounting apparatus taken along line B-B in FIG. 4 and illustrating that the driver mount-side heat supply support member and the driver-side heat supply support member are simultaneously in contact with the driver mount portion and the driver, respectively, if the thickness of the driver mount portion is the designed value.

FIG. 12 is a cross-sectional view of the driver mounting apparatus taken along line A-A in FIG. 4 and illustrating that the driver mount portion and the driver sandwiched between the driver mount-side heat supply support member and the driver-side heat supply support member are pressed and heated, if the thickness of the driver mount portion is the designed value, and a mounting operation is completed.

FIG. 13 is a cross-sectional view of the driver mounting apparatus taken along line B-B in FIG. 4 and illustrating that the driver mount portion and the driver sandwiched between the driver mount-side heat supply support member and the driver-side heat supply support member are pressed and heated, if the thickness of the driver mount portion is the designed value, and a mounting operation is completed.

FIG. 14 is a cross-sectional view of the driver mounting apparatus taken along line A-A in FIG. 4 and illustrating that the driver mount-side heat supply support member is first in contact with the driver mount portion, if the driver mount portion and the driver have a same thickness.

FIG. 15 is a cross-sectional view of the driver mounting apparatus taken along line A-A in FIG. 4 and illustrating that the driver-side heat supply support member is later in contact with the driver, if the driver mount portion and the driver have a same thickness.

FIG. 16 is a cross-sectional view of the driver mounting apparatus taken along line A-A in FIG. 4 and illustrating that the driver mount-side heat supply support member is first in contact with the driver mount portion, if the driver mount portion has a thickness greater than that of the driver.

FIG. 17 is a cross-sectional view of the driver mounting apparatus taken along line A-A in FIG. 4 and illustrating that the driver-side heat supply support member is in contact with the driver, if the driver mount portion has a thickness greater than that of the driver.

FIG. 18 is a cross-sectional view of the driver mounting apparatus taken along line A-A in FIG. 4 and illustrating that the driver mount-side heat supply support member is first in contact with the driver mount portion, if the driver mount portion has a thickness smaller than that of the driver.

FIG. 19 is a cross-sectional view of the driver mounting apparatus taken along line A-A in FIG. 4 and illustrating that the driver-side heat supply support member is in contact with the driver, if the driver mount portion has a thickness smaller than that of the driver.

FIG. 20 is a graph representing warpage of the driver mount portion after a pressing process with using a driver mounting apparatus according to Comparative Example of comparative experiments.

FIG. 21 is a graph representing warpage of the driver mount portion after the pressing process with using a driver mounting apparatus according to Example of the comparative experiments.

FIG. 22 is a block diagram illustrating an electrical configuration of a driver mounting apparatus according to a second embodiment of the present invention.

FIG. 23 is a cross-sectional view of the driver mounting apparatus illustrating an operation of a driver mount-side heat supply support member that comes first in contact with the driver mount portion since an initial state.

FIG. 24 is a cross-sectional view of the driver mounting apparatus illustrating an operation of a driver-side heat supply support member that comes first in contact with the driver since an initial state.

FIG. 25 is a cross-sectional view of the driver mounting apparatus according to a third embodiment of the present invention illustrating that moving speed of the driver mount-side heat supply support member and the driver-side heat supply support member is set relatively fast and set relatively slow thereafter.

FIG. 26 is a cross-sectional view of the driver mounting apparatus illustrating that moving speed of the driver mount-side heat supply support member and the driver-side heat supply support member is set relatively slow and set relatively fast thereafter.

FIG. 27 is a cross-sectional view of a flexible printed circuit board mounting apparatus according to a fourth embodiment of the present invention, the flexible printed circuit board mounting apparatus being in an initial state.

FIG. 28 is a plan view illustrating a plan view configuration of a liquid crystal panel, a flexible printed circuit board, and a printed circuit board according to a fifth embodiment of the present invention.

FIG. 29 is across sectional view of a flexible printed circuit board mounting apparatus that is taken along line C-C in FIG. 28 and in an initial state.

FIG. 30 is a block diagram illustrating an electrical configuration of a driver mounting apparatus according to a seventh embodiment of the present invention.

FIG. 31 is a cross sectional view of a driver mounting apparatus in an initial state.

FIG. 32 is a block diagram illustrating an electrical configuration of a driver mounting apparatus according to a seventh embodiment of the present invention.

FIG. 33 is a cross sectional view of the driver mounting apparatus that is in an initial state.

### MODE FOR CARRYING OUT THE INVENTION

### First Embodiment

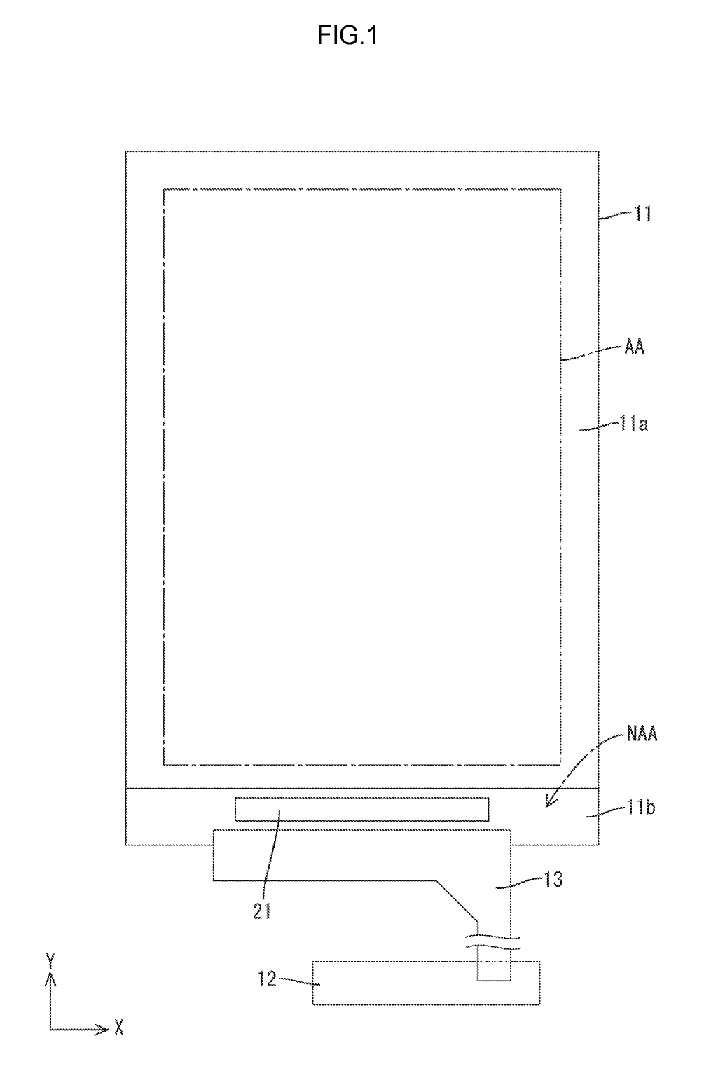

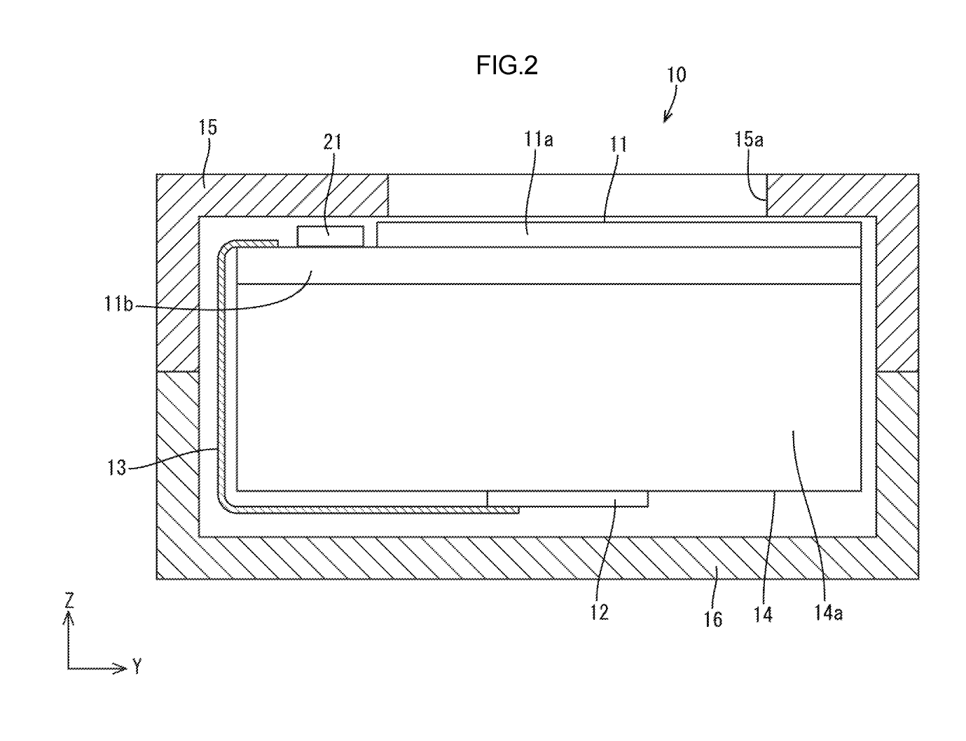

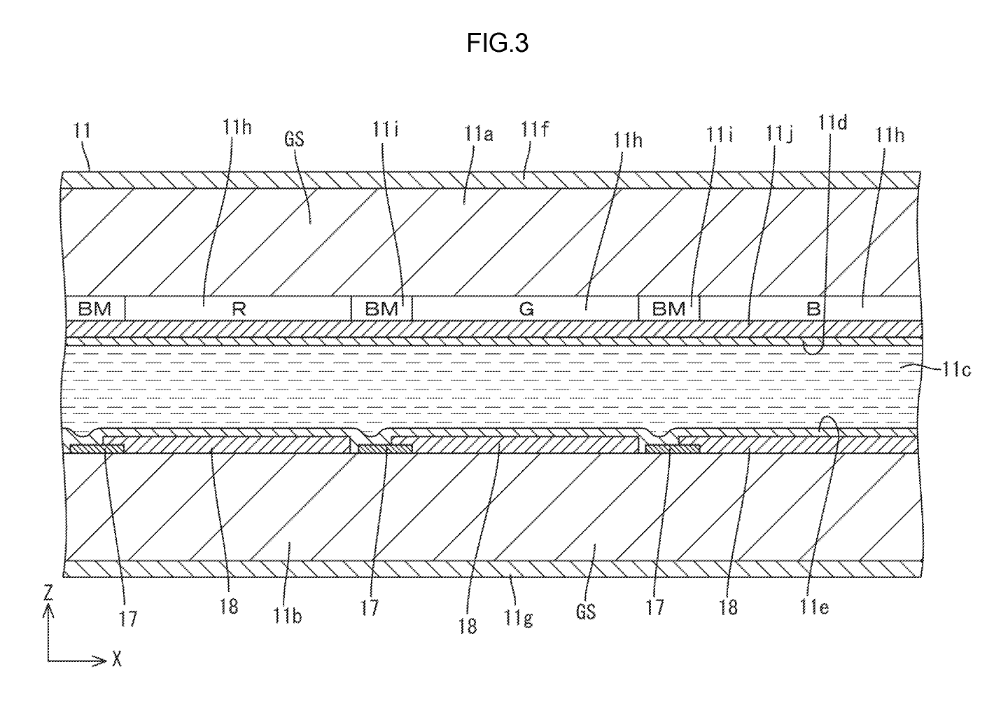

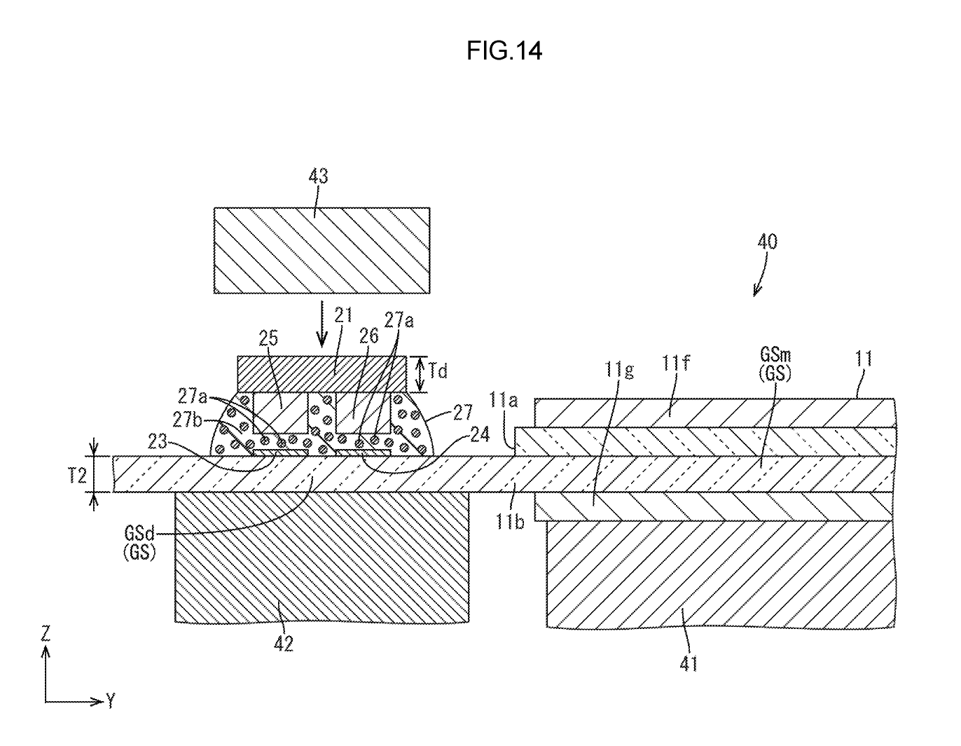

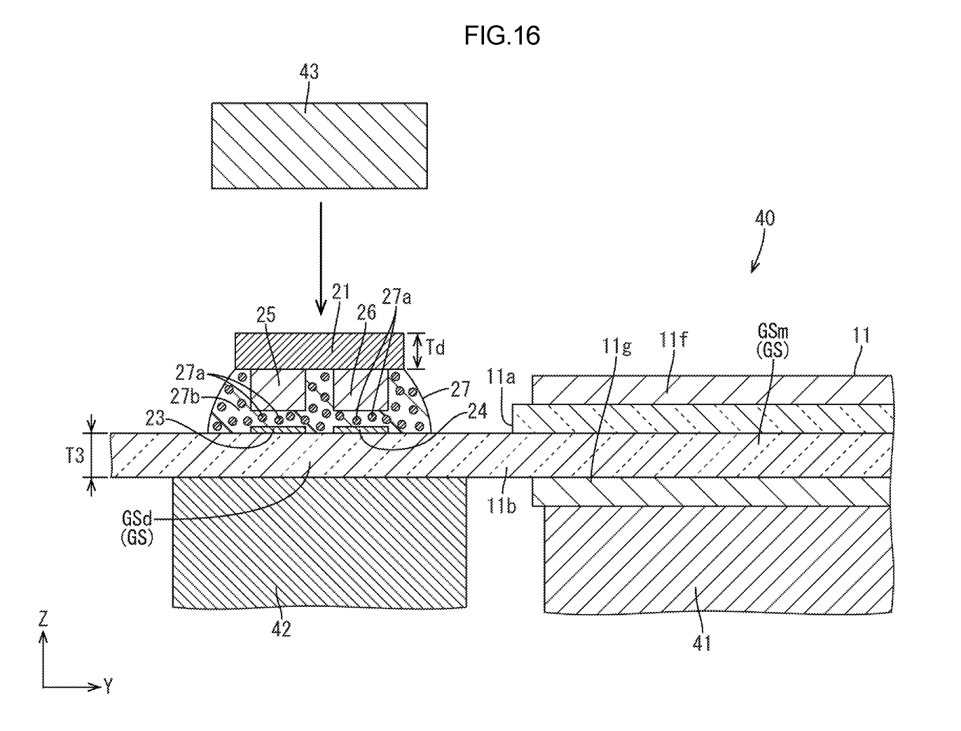

A first embodiment will be described with reference to FIGS. 1 to 21. In this section, a method of manufacturing a liquid crystal panel (display panel) 11 included in a liquid crystal display device 10 and a driver mounting apparatus (manufacturing apparatus) 40 used in the manufacturing of the liquid crystal panel 11 will be described. X-axes, Y-axes, and Z-axes may be present in the drawings. The axes in each drawing correspond to the respective axes in other drawings. The Y-axis direction corresponds to a vertical direction in FIGS. 2 and 3. An upper side in FIGS. 2 and 3 corresponds to a front side of the liquid crystal display device 10. A lower side in FIGS. 2 and 3 corresponds to a rear side of the liquid crystal display device 10.

As illustrated in FIGS. 1 and 2, the liquid crystal display device 10 includes the liquid crystal panel 11, a driver (a component) 21, a control circuit board (an external signal supply) 12, a flexible printed circuit board (an external connecting member) 13, a backlight unit (a lighting unit) 14. The driver 21 is mounted on the liquid crystal panel 11 for driving the liquid crystal panel 11. The control circuit board 12 is for externally supplying various input signals to the driver 21. The flexible printed circuit board 13 establishes electrical connection between the liquid crystal panel 11 and the external control circuit board 12. The backlight unit 14 is an external light source for supplying light to the liquid crystal panel 11. The liquid crystal display device 10 further includes front and rear exterior components 15 and 16 that are used in a pair for holding the liquid crystal panel 11 and the backlight unit 14 that are fixed together. The front exterior component 15 has an opening 15a through which images displayed on the liquid crystal panel 11 can be viewed from the outside. The liquid crystal display device 10 according to this embodiment is for various kinds of electronic devices (not illustrated) including handheld terminals (including electronic book readers and PDAs), mobile phones (including smartphones), notebook computers (including tablet computers), digital photo frames, portable video game players, and electronic papers. Therefore, a screen size of the liquid crystal panel 11 of the liquid crystal display device 10 is in a range from some inches to ten plus some inches, that is, the size commonly categorized as a small size or a small-to-mid size.

The backlight unit 14 will be briefly described. As illustrated in FIG. 2, the backlight unit 14 includes a chassis 14a, light sources that are not illustrated, and an optical member that are not illustrated. The chassis 14a has a box-like shape with an opening on the front side (a liquid crystal panel 11 side). The light sources (e.g., cold cathode tubes, LEDs, and organic ELs) are disposed inside the chassis 14a. The optical member is disposed over the opening of the chassis 14a. The optical member has a function for converting light from the light sources into planar light.

Next, the liquid crystal panel 11 will be described. As illustrated in FIG. 1, the liquid crystal panel 11 has a vertically-long quadrilateral (or rectangular) overall shape. The display area (an active area) AA is arranged off-centered to one of edges at an end of a long dimension of the liquid crystal panel 11 (on the upper side in FIG. 1). The driver 21 and the flexible printed circuit board 13 are mounted to a portion of the liquid crystal panel 11 closer to an edge at the other end of the long dimension of the liquid crystal panel 11 (on the lower side in FIG. 1). An area of the liquid crystal panel 11 outside a display area AA is the non-display area (non-active area) NAA in which images are not displayed. The non-display area NAA includes a mounting area to which the driver 21 and the flexible printed circuit board 13 are mounted. In FIG. 1, a chain line that forms a box slightly smaller than a CF substrate 11a indicates an outer boundary of the display area AA and the area outside the chain line is the non-display area NAA.

As illustrated in FIG. 3, the liquid crystal panel 11 includes a pair of transparent substrates 11a and 11b (with high light transmissivity) and a liquid crystal layer 11c between the substrates 11a and 11b. The liquid crystal layer 11c includes liquid crystal molecules that are substances having optical characteristics that change according to application of electric field. The substrates 11a and 11b are bonded together with a sealing agent, which is not illustrated, with a cell gap maintained therebetween. The cell gap corresponds to a thickness of the liquid crystal layer 11c. The substrates 11a and 11b include glass substrates (substrates) GS, respectively. The glass substrates GS may be made of alkali-free glass or silica glass. Various kinds of films are formed in layers on the glass substrates GS using a known lithography method. One of the substrates 11a and 11b at the front is the CF substrate (a counter substrate) 11a and one at the rear is the array substrate (a mounting substrate, a component substrate, an active matrix substrate) 11b. As illustrated in FIGS. 1 and 2, the CF substrate 11a has a short dimension about equal to that of the array substrate 11b and a long dimension smaller than that of the array substrate 11b. The CF substrate 11a is bonded to the array substrate 11b with one of ends of the long dimension (an upper end in FIG. 1) aligned with that of the array substrate 11b. The CF substrate 11a does not overlap an end portion of the array substrate 11b at the other end of the long dimension of the array substrate 11b (a lower end in FIG. 1), that is, front and back surfaces of the end portion of the array substrate 11b are exposed to the outside. The end portion of the array substrate 11b includes a mounting area in which the driver 21 and the flexible printed circuit board 13 are mounted. Alignment films 11d and 11e are formed on inner surfaces of the substrates 11a and 11b, respectively, for aligning the liquid crystal molecules included in the liquid crystal layer 11c. Polarizing plates 11f and 11g are bonded to outer surfaces of the substrates 11a and 11b, respectively.

Next, components on the array substrate 11b and the CF substrate 11a in the display area AA will be described in detail. As illustrated in FIG. 3, a number of the TFTs (thin film transistors) 17 and a number of pixel electrodes 18 are arranged in a matrix on the inner surface of the array substrate 11b (the liquid crystal layer 11c side, the opposed surface side opposed to the CF substrate 11a). Furthermore, the gate lines and the source lines 20 (both not illustrated) are arranged in a grid to surround the TFTs 17 and the pixel electrodes 18. Namely, the TFTs 17 and the pixel electrodes 18 are arranged at the respective intersections of the gate lines and the source lines and in a grid. The gate lines and the source lines are connected to gate electrodes and source electrodes of the TFTs 17, respectively. The pixel electrodes 18 are connected to drain electrodes 17c of the TFTs 17. Each of the pixel electrodes 18 has a vertically long rectangular shape in a plan view. The pixel electrodes 18 are made of transparent electrode material such as indium tin oxide (ITO) and zinc oxide (ZnO). Furthermore, an auxiliary capacitor line (not illustrated) may be formed to be parallel to the gate lines and to cross the pixel electrodes 18.

As illustrated in FIG. 3, color filters 11h are formed on the CF substrate 11a. The color filters 11h include red (R), green (G), and blue (B) color portions are arranged in a matrix to overlap the pixel electrodes 18 on the array substrate 11b in a plan view. A light blocking layer 11i having a grid shape (a black matrix) is formed between the color portions included in the color filters 11h for reducing color mixture. The light blocking layer 11i is arranged to overlap the gate lines and the source lines in a plan view. A counter electrode 11j is formed in a solid pattern on surfaces of the color filters 11h and the light blocking layer 11i. The counter electrode 11j is opposed to the pixel electrodes 18 on the array substrate 11b. In the liquid crystal panel 11, as illustrated in FIGS. 1 to 3, the R (red) color portion, the G (green) color portion, the B (blue) color portion, and three pixel electrodes 18 opposed to the color portions form a display pixel that is a display unit. Each display pixel includes a red pixel including the R color portion, a green pixel including the G color portion, and a blue pixel including the B color portion. The color pixels are repeatedly arranged along a row direction (the X-axis direction) on a plate surface of the liquid crystal panel to form lines of pixels. The lines of pixels are arranged along the column direction (the Y-axis direction).

The components connected to the liquid crystal panel 11 will be described. As illustrated in FIGS. 1 and 2, the control circuit board 12 is attached to the back surface of the chassis 14a of the backlight unit 14 (an outer surface on a side opposite from the liquid crystal panel 11 side) with a screw or other fixing member. The control circuit board 12 includes a substrate made of paper phenol or glass epoxy resin and electronic components mounted on the substrate for supplying various kinds of input signals to the driver 21. The control circuit board 12 further includes predetermined traces (conductive lines), which are not illustrated, routed on the substrate. One of ends (a first end) of the flexible printed circuit board 13 is electrically and mechanically connected to the control circuit board 12 via an anisotropic conductive film, which is not illustrated.

As illustrated in FIG. 2, the flexible printed circuit board (FPC board) 13 includes a base member made of synthetic resin (e.g., polyimide resin) having an insulating property and flexibility. The flexible printed circuit board 13 includes traces (not illustrated) on the base member. As described earlier, the first end, which is one of ends of the flexible printed circuit board 13 with respect to the length direction thereof, is connected to the control circuit board 12 on the back surface of the chassis 14a. The other end (a second end) of the flexible printed circuit board 13 is connected to the second end of the array substrate 11b of the liquid crystal panel 11. Namely, the flexible printed circuit board 13 is folded such that a shape in a cross-sectional view is a U-like shape. The ends of the flexible printed circuit board 13 with respect to the length direction include exposed portions of traces which form terminals (not illustrated). The terminals are electrically connected to the control circuit board 12 and the liquid crystal panel 11. According to the configuration, the input signals supplied by the control circuit board 12 are transmitted to the liquid crystal panel 11.

As illustrated in FIG. 1, the driver 21 includes an LSI chip including a driver circuit therein. The driver 21 operates according to signals supplied by the control circuit board 12, which is a signal source, process the input signals supplied by the control circuit board 12, which is a signal source, generates output signals, and sends the output signals to the display area AA of the liquid crystal panel 11. The LSI chip included in the driver 21 includes traces and components formed on a silicon wafer that contains silicon with high purity. The driver 21 has a horizontally long rectangular shape in the plan view. The driver 21 is orientated such that a long-side direction thereof is along the short-side direction of the liquid crystal panel 11. The driver 21 is directly mounted on the array substrate 11b in the non-display area NAA of the liquid crystal panel 11 with the COG (chip on glass) mounting technology. The long-side direction (the longitudinal direction) of the driver 21 corresponds with the X-axis direction (the short-side direction) of the liquid crystal panel 11) and the short-side direction (the direction perpendicular to the longitudinal direction) corresponds with the Y-axis direction (the long-side direction of the liquid crystal panel 11).

Next, a connection configuration of the flexible printed circuit board 13 and the driver 21 that are connected to the non-display area NAA of the array substrate 11b will be described. As illustrated in FIG. 1, edge portions of the respective driver 21 and the flexible printed circuit board 13 are mounted on a non-overlapping portion of the non-display area NAA of the array substrate 11b, the non-overlapping portion not overlapping the CF substrate 11a. An edge portion of the flexible printed circuit board 13 is arranged on an edge portion of the array substrate 11b along a short side thereof. That is, the driver 21 is arranged in the non-display area NAA and between the display area AA and the flexible printed circuit board 13. Another edge portion of the flexible printed circuit board 13 (to be mounted on the liquid crystal panel 11) is on an opposite side from the display area AA with respect to the driver 21 (on an edge side of the array substrate 11b). The edge of the flexible printed circuit board 13 is mounted on a middle portion in a short-side edge portion of the array substrate 11b. The mounted edge of the flexible printed circuit board 13 extends along the short-side edge of the array substrate 11b (the short-side direction, the X-axis direction). A dimension of the edge portion of the flexible printed circuit board 13 mounted on the array substrate 11b is smaller than a long-side dimension of the array substrate 11b. The driver 21 is mounted in a middle portion of the non-display area NAA with respect to the short-side direction of the array substrate 11b such that the long-side direction of the driver 21 corresponds with the short-side direction of the array substrate 11b (the X-axis direction).

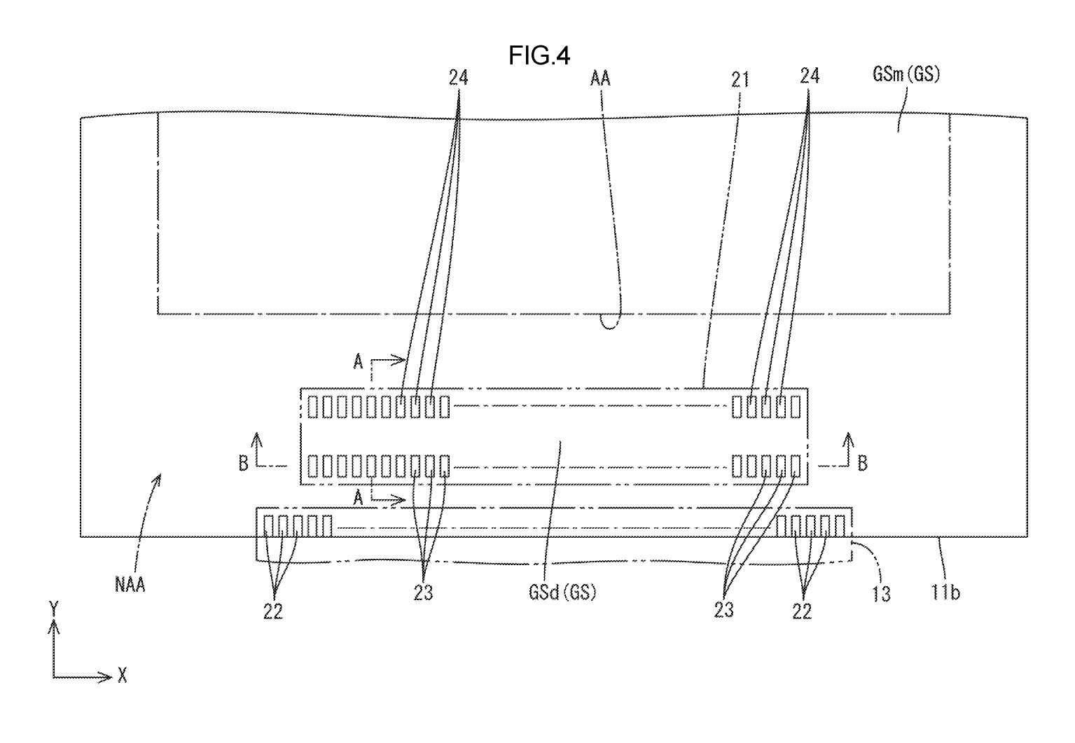

As illustrated in FIG. 4, external connection terminals 22 are formed in the mounting area of the array board 11b in which the flexible printed circuit board 13 is mounted. The external connection terminals 22 receive supply of input signals from the flexible printed circuit board 13. Panel-side input terminals (board-side input terminals) 23 and panel-side output terminals (board-side output terminals) 24 are mounted in the mounting area of the array substrate 11b in which the driver 21 is to be mounted. Input signals are supplied from the panel-side input terminals to the driver 21, and output signals from the driver 21 are supplied to the panel-side output terminals 24. Relay traces (not illustrated) are arranged in the non-display area NAA and between the flexible printed circuit board 13 mounting area and the driver 21 mounting area, and the external connection terminals 22 and the panel-side input terminals 23 are electrically connected to each other via the relay traces. The driver 21 includes driver-side input terminals (mounting component-side input terminals) 25 and driver-side output terminals (mounting component-side output terminals) 26. The driver-side input terminals 25 are electrically connected to the panel-side input terminals 23, and the driver-side output terminals 26 are electrically connected to the panel-side output terminals 24. In FIG. 4, the flexible printed circuit board 13 and the driver 21 are illustrated with two-dot chain lines. In FIG. 4, a dashed line indicates an outer boundary of the display area AA and the area outside the chain line is the non-display area NAA.

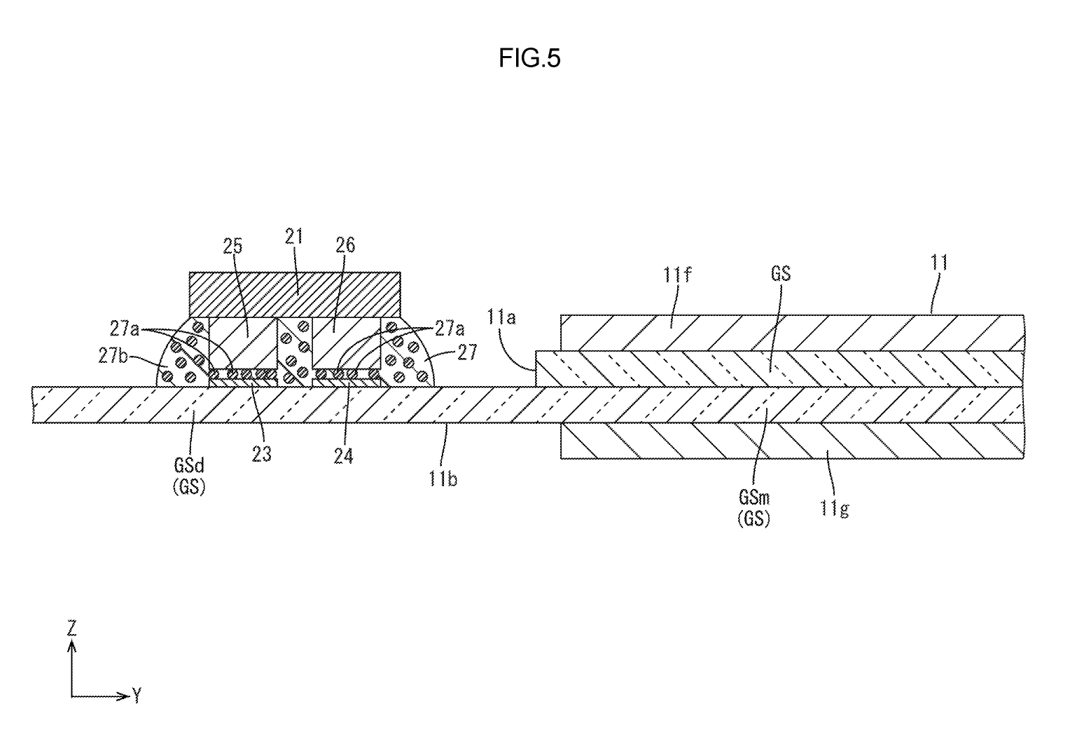

As illustrated in FIG. 5, each of the panel-side input terminals 23 and the panel-side output terminals 24 is made of a metal thin film similar to that of the gate lines and the source lines, and surfaces of the metal thin film is covered with transparent electrode material such as ITO or ZnO same as the pixel electrode 18. Therefore, the panel-side input terminals 23 and the panel-side output terminals 24 are formed on the array substrate 11b with the known photolithography method at a same time when the gate lines or the source lines, and the pixel electrodes 18 are formed with patterning in a process of manufacturing the liquid crystal panel 11 (the array substrate 11b). An anisotropic conductive film (ACF, anisotropic conductive material) 27 is arranged on the panel-side input terminals 23 and the panel-side output terminals 24. The driver-side input terminals 25 of the driver 21 are electrically connected to the panel-side input terminals 23 and the driver-side output terminals 26 are electrically connected to the panel-side output terminals 24 via conductive particles 27a contained in the anisotropic conductive film 27. The anisotropic conductive film 27 includes the conductive particles 27a made of metal material and thermosetting resin 27b in which the conductive particles 27a are dispersed. The terminals 23-26 are connected to each other via the anisotropic conductive film 27 by mounting the driver 21 on the array substrate 11b using a driver mounting apparatus 40, which will be described in detail later. As is not illustrated, the external connection terminals 22 have a cross-sectional configuration similar to those of the panel-side input terminals 23 and the panel-side output terminals 24, and the external connection terminals 22 are electrically connected to the terminals of the flexible printed circuit board 13 via the anisotropic conductive film.

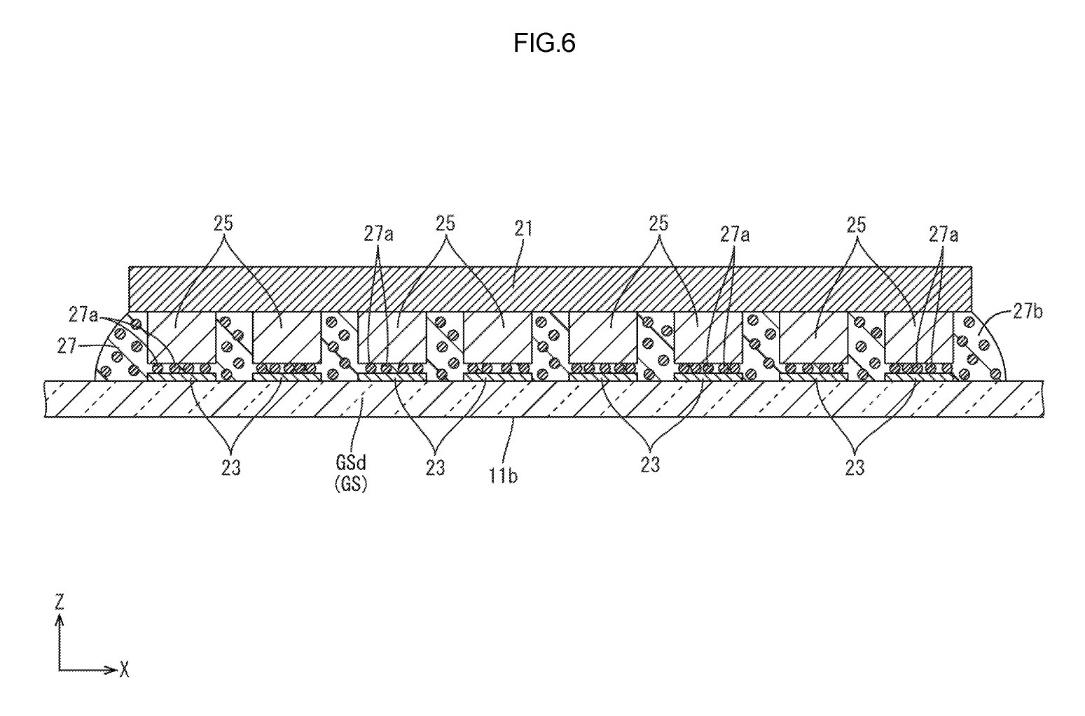

As illustrated in FIGS. 4 and 5, the panel-side input terminals 23 and the panel-side output terminals 24 are disposed in a portion of the array substrate 11b overlapping the driver 21 with a plan view, that is, a driver 21-mounting area. A group of the panel-side input terminals 23 and a group of the panel-side output terminals 24 are arranged in the Y-axis direction (in a direction that the driver 21 and the display area AA (the flexible printed circuit board 13) are arranged) with a certain distance therebetween. The panel-side input terminals 23 are arranged closer to the flexible printed circuit board 13 (on an opposite side from a display area AA side) in the driver 21-mounting area of the array substrate 11b, and the panel-side output terminals 24 are closer to the display area AA (on an opposite side from a flexible printed circuit board 13-side). As illustrated in FIG. 6, the panel-side input terminals 23 are arranged linearly and the panel-side output terminals 24 are arranged linearly in the X-axis direction, that is, in a long-side direction (a longitudinal direction) of the driver 21 with a certain distance therebetween. FIG. 6 illustrates the cross-sectional configuration of the input terminals 23 and 25, and the output terminals 24 and 26 have the similar cross-sectional configuration thereof.

As illustrated in FIG. 5, the driver-side input terminals 25 and the driver-side output terminals 26 are made of metal material having good conductivity such as gold and are metal bumps (projections) that project from a bottom surface (a surface opposite the array substrate 11b) of the driver 21. Each of the driver-side input terminals 25 and the driver-side output terminals 26 is connected to a processing circuit included in the driver 21. Input signals are input via the driver-side input terminals 25 and processed with the processing circuit and the signals are output to the driver-side output terminals 26. As illustrated in FIG. 6, similarly to the panel-side input terminals 23 are arranged linearly and the panel-side output terminals 24, the driver-side input terminals 25 are arranged linearly and the driver-side output terminals 26 are arranged linearly in the X-axis direction, that is, in a long-side direction of the driver 21, with a certain distance therebetween.

The liquid crystal panel 11 has been required to be reduced in thickness or weight and accordingly, the glass substrate GS of the CF substrate 11a and the array substrate 11b included in the liquid crystal panel 11 has been required to be thinner. The glass substrate GS of the CF substrate 11a and the array substrate 11b may be reduced in thickness. However, the degree to which the thickness is reduced in the manufacturing process is limited. Even if the thickness of the glass substrate GS can be reduced, deflection or warpage are likely to be caused and flatness of the glass substrate GS is hardly maintained. Errors are likely to be caused when various films are formed on the glass substrate GS with patterning. In this embodiment, after various films are formed on the glass substrates of the CF substrate 11a and the array substrate 11b with patterning, each of the glass substrates GS is subjected to etching (wet etching) on a plate surface opposite from a plate surface having the various films, that is, an outer plate surface. Thus, the glass substrate GS is subjected to thinning. Accordingly, the glass substrate GS can be reduced in thickness with being manufactured with the previous method and with less errors being caused in processes of film forming and patterning. However, it is difficult to reduce a thickness of the glass substrate GS evenly over an entire area within a plane surface with thinning by etching. Therefore, undulation may be caused on an outer plate surface of the glass substrate GS to be subjected to etching and a plate thickness of the glass substrate GS may be uneven within a plane surface of the outer plate surface. As a result, in a previous driver mounting device, pressure and heat may be applied to the driver at various timings, and mounting errors may be caused.

As described before, the glass substrate GS has been required to be thinner according to the thinning of the liquid crystal panel 11. Accordingly, the driver 21 also has been required to be thinner. Specifically, the thickness of the glass substrate GS has been within a range of 0.2 mm to 0.7 mm, and is required to be within a range of 0.1 mm to 0.15 mm. The thickness of the driver 21 has been within a range of 0.2 mm to 0.3 mm, and is required to be within a range of 0.12 mm to 0.18 mm. Namely, the thickness of the glass substrate GS has been greater than that of the driver 21. However, the thickness of the glass substrate GS may be required to be smaller than that of the driver 21. Thus, if the driver 21 and the glass substrate GS is required to be thinner and thinner, following problems may be caused. In mounting the driver 21, the driver 21 is placed on the glass substrate GS of the array substrate 11b via the anisotropic conductive film 27 and then, the driver 21 and the glass substrate GS is pressed by the driver mounting device and the thermosetting resin 27b contained in the anisotropic conductive film 27 is thermally cured. Heat is transferred to the anisotropic conductive film 27 from the driver mounting device via the driver 21 and the glass substrate GS, and the driver 21 and the glass substrate GS are thermally expanded and thermally shrunk due to the heat. The thermal expansion/shrinkage amount of the driver 21 differs from that of the glass substrate GS, and if stress generated due to the difference is greater than mechanical strength of the driver 21 and the glass substrate GS, warpage is caused in the driver 21 and the glass substrate GS. The driver 21 and the glass substrate GS are likely to have lowered mechanical strength according to the thinning thereof, and warpage caused due to the difference in the thermal expansion/shrinkage amount is likely to be caused according to the thinning of the driver 21 and the glass substrate GS.

A following method may be applied to cause less warpage in the driver 21 and the glass substrate GS. In the driver mounting device, the driver 21 is heated and the glass substrate GS of the array substrate 11b may be also heated to reduce the difference between the thermal expansion/shrinkage amount of the driver 21 and that of the glass substrate GS. However, with such a method, the glass substrate GS is heated after the glass substrate GS is placed on the stage of the driver mounting device and until the driver 21 is pressured by a pressure head. Therefore, the thermosetting resin 27b of the anisotropic conductive film 27 may be thermally cured previously before being pressured by the pressure head. As result, mounting errors may be caused.

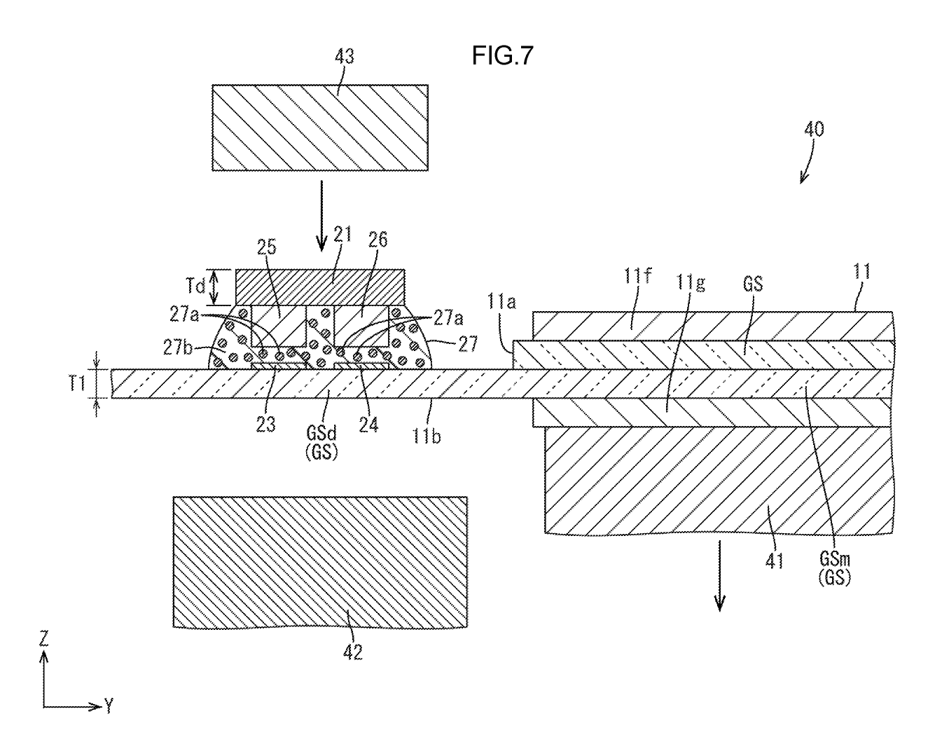

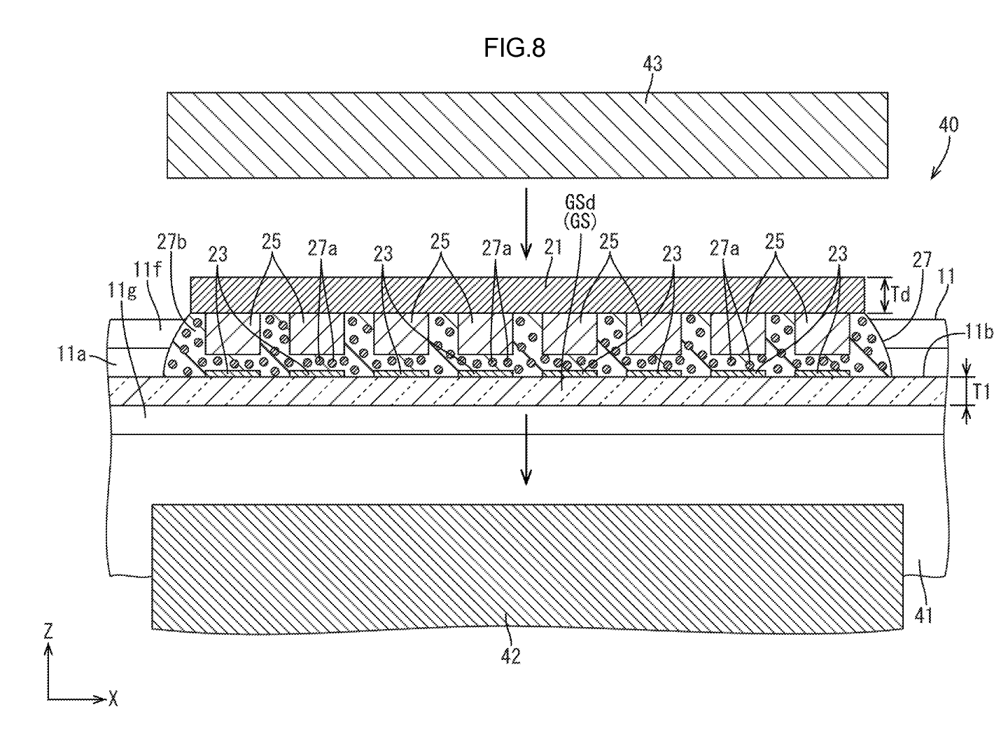

In the present embodiment, the driver mounting apparatus 40 for mounting the driver 21 on the array substrate 11b has a following configuration. As illustrated in FIGS. 7 and 8, the driver mounting apparatus 40 includes a substrate support member 41, a driver mount-side heat supply support member (a component mount-side heat supply support member) 42, and a driver-side heat supply support member (a mounting component-side heat supply support member) 43. The substrate support member 41 is arranged on a rear side with respect to the glass substrate GS included in the array substrate 11b, and is arranged an opposite side from the driver 21 and supports a substrate main portion GSm of the glass substrate GS. The driver mount-side heat supply support member 42 is arranged on the rear side with respect to the glass substrate GS included in the array substrate 11b, that is, on a same side with the substrate support member 41. The driver mount-side heat supply support member 42 supports a driver mount portion (a component mount portion) GSd of the glass substrate GS and supplies heat to the driver mount portion GSd where the driver 21 is mounted. The driver-side heat supply support member 43 is arranged on a same side with the driver 21, that is, on an opposite side from the substrate support member 41 and the driver mount-side heat supply support member 42, and supports the driver 21 and supplies heat to the driver 21. The driver mount-side heat supply support member 42 is not movable in the Z-axis direction, that is, in a direction that the glass substrate GS and the driver 21 are overlapped. The substrate support member 41 and the driver-side heat supply support member 43 are movable in the Z-axis direction. Accordingly, the glass substrate GS and the driver 21 are sandwiched between the driver mount-side heat supply support member 42 and the driver-side heat supply support member 43 and pressed.

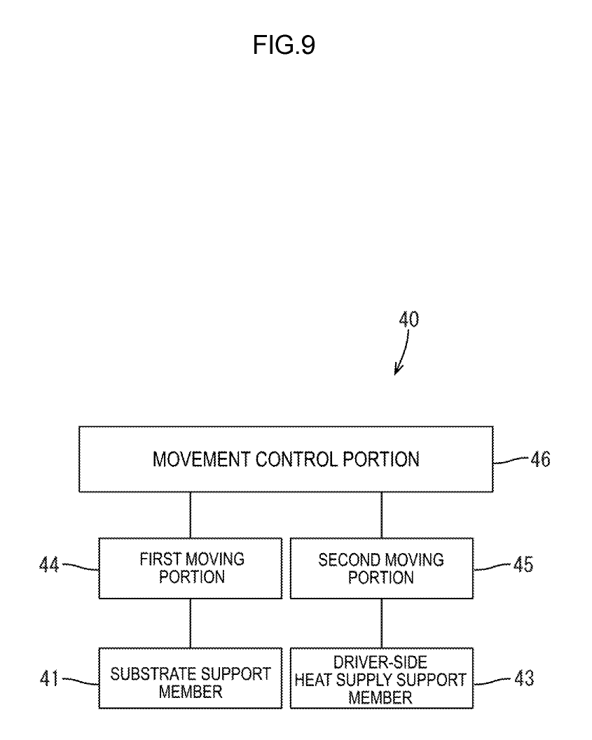

As illustrated in FIG. 9, the driver mounting apparatus 40 includes a first moving portion 44, a second moving portion 45, and a movement control portion 46. The first moving portion 44 moves the substrate support member 41 to relatively move the driver mount portion GSd and the driver mount-side heat supply support member 42 in the Z-axis direction (an overlapping direction). The second moving portion 45 moves the driver-side heat supply support member 43 to relatively move the driver 21 and the driver-side heat supply support member 43. The movement control portion 46 controls the first moving portion 44 and the second moving portion 45. The first moving portion 44 moves the substrate support member 41 upward and downward in the Z-axis direction. Accordingly, the driver mount portion GSd of the glass substrate GS supported by the substrate support member 41 is relatively moved to be closer to or away from the driver mount-side heat supply support member 42 in the Z-axis direction. The second moving portion 45 moves the driver-side heat supply support member 43 upward and downward in the Z-axis direction. Accordingly, the driver-side heat supply support member 43 is relatively moved to be closer to or away from the driver 21 in the Z-axis direction. The movement control portion 46 controls the first moving portion 44 to control moving speed of the substrate support member 41 that is moved in the Z-axis direction, that is, relative moving speed of the driver mount portion GSd of the glass substrate GS supported by the substrate support member 41 relative to the driver mount-side heat supply support member 42. The movement control portion 46 controls the second moving portion 45 to control moving speed of the driver-side heat supply support member 43 that is moved in the Z-axis direction, that is, relative moving speed of the driver-side heat supply support member 43 relative to the driver 21.

As illustrated in FIGS. 7 and 8, the substrate support member 41 vacuum sucks and supports the substrate main portion GSm of the glass substrate GS of the array substrate 11b from a rear side to hold the glass substrate GS. The substrate main portion GSm supported by the substrate support member 41 is a most part of the glass substrate GS of the array substrate 11b except for the driver mount portion GSd (specifically, a portion of the array substrate 11b overlapping the CF substrate 11a). The substrate support member 41 has a plan-view size that is substantially same or greater than that of the substrate main portion GSm of the glass substrate GS of the array substrate 11b. Accordingly, the substrate support member 41 supports and holds an entire area of the substrate main portion GSm. The substrate support member 41 is supported by a lifting/lowering device (not illustrated) to be lifted and lowered in the Z-axis direction (in the overlapping direction in which the glass substrate GS and the driver 21 overlap, along a normal line to a plate surface of the glass substrate GS). The substrate support member 41 supporting the glass substrate GS is relatively moved in the Z-axis direction to be closer to or away from the driver mount-side heat supply support member 42. The lifting/lowering device that supports the substrate support member 41 to be lifted and lowered is the first moving portion 44 illustrated in FIG. 9. The lifting/lowering device lifts and lowers the substrate support member 41 with a driving source such as a motor and controls lifting/lowering speed (moving speed, relative moving speed). The substrate support member 41 does not directly vacuum suck the glass substrate GS included in the array substrate 11b but directly vacuum sucks the polarizing plate 11g attached to the array substrate 11b to indirectly hold the glass substrate GS.

As illustrated in FIGS. 7 and 8, the driver mount-side heat supply support member 42 supports the driver mount portion GSd of the glass substrate GS of the array substrate 11b from the rear side and receives from the rear side the driver 21 and the driver mount portion GSd that are pressed by the driver-side heat supply support member 43. The driver mount-side heat supply support member 42 is made of metal material as a whole to have good mechanical strength and thermal conductivity and includes a heater inside thereof as heat supply means (heating means). The driver mount portion GSd received by the driver mount-side heat supply support member 42 is a part of the glass substrate GS included in the array substrate 11b except for the substrate main portion GSm (specifically, a portion of the array substrate 11b not overlapping the CF substrate 11a). Therefore, the driver mount portion GSd has a plan-view size sufficiently greater than that of the driver 21. The driver mount-side heat supply support member 42 has a plan-view size greater than that of the driver 21 and substantially same as that of the driver mount portion GSd of the glass substrate GS included in the array substrate 11b. Accordingly, the driver mount-side heat supply support member 42 holds an entire area of the driver mount portion GSd. The driver mount-side heat supply support member 42 has a horizontally-long quadrilateral plan-view shape following the shape of the driver mount portion GSd and the long-side direction thereof matches the X-axis direction and the short-side direction thereof matches the Y-axis direction. The driver mount-side heat supply support member 42 is fixed not to move in the Z-axis direction. The driver mount-side heat supply support member 42 is made of metal and has a great rigidity. A receiving surface of the driver mount-side heat supply support member 42 receiving the driver mount portion GSd is processed with high processing accuracy to have flatness with high precision. The receiving surface of the driver mount-side heat supply support member 42 is in contact with an outer plate surface of the driver mount portion GSd to receive the driver mount portion GSd. The thermosetting resin 27b contained in the anisotropic conductive film 27 that is between the driver 21 and the driver mount portion GSd is thermally cured by heat transferred from the driver mount-side heat supply support member 42 to the driver mount portion GSd.

As illustrated in FIGS. 7 and 8, the driver-side heat supply support member 43 is arranged on a front side with respect to the glass substrate GS included in the array substrate 11b, that is, on an opposite side from the substrate support member and the driver mount-side heat supply support member 42. The driver 21 is (sandwiched) between the driver-side heat supply support member 43 and the driver mount portion GSd of the glass substrate GS received by the driver mount-side heat supply support member 42. The driver-side heat supply support member 43 is made of metal material as a whole to have good mechanical strength and thermal conductivity and includes a heater inside thereof as heat supply means (heating means). The driver-side heat supply support member 43 is supported by the lifting/lowering device (not illustrated) to be lifted and lowered in the Z-axis direction (in the overlapping direction in which the glass substrate GS and the driver 21 overlap, along the normal line to a plate surface of the glass substrate GS). The driver-side heat supply support member 43 is relatively moved to be closer to or away from the driver mount-side heat supply support member 42 and the driver 21 placed on the glass substrate GS. The lifting/lowering device that supports the driver-side heat supply support member 43 to be lifted and lowered is the second moving portion 45 illustrated in FIG. 9. The lifting/lowering device lifts and lowers the driver-side heat supply support member 43 with a driving source such as a motor and controls lifting/lowering speed (moving speed, relative moving speed). The driver-side heat supply support member 43 presses and heats the driver 21 sandwiched between the driver-side heat supply support member 43 and the driver mount portion GSd of the glass substrate GS. The terminals 25, 26 on the driver 21 side are electrically connected to the terminals 23, 24 on the array substrate 11b side via the conductive particles 27a contained in the anisotropic conductive film 27 by pressure force applied from the driver-side heat supply support member 43 to the driver 21. The thermosetting resin 27b included in the anisotropic conductive film 27 that is between the driver 21 and the driver mount portion GSd is thermally cured by heat transferred from the driver-side heat supply support member 43 to the driver 21.

The movement control portion 46 includes a central processing unit (CPU), which is not illustrated, and as illustrated in FIG. 9, the movement control portion 46 is configured to control the first moving portion 44 and the second moving portion 45. The movement control portion 46 controls driving of the motor, which is a driving source for driving the first moving portion 44 and the second moving portion 45, to control lifting/lowering speed of the substrate support member 41 and the driver-side heat supply support member 43 that are lifted/lowered by the first moving portion 44 and the second moving portion 45, respectively. Specifically, the movement control portion 46 controls the first moving portion 44 and the second moving portion 45 to keep the lifting/lowering speed of the substrate support member 41 and the driver-side heat supply support member 43 to be a constant value or change (increase or decrease) the lifting/lowering speed. The movement control portion 46 controls the lifting/lowering speed of the substrate support member 41 and the driver-side heat supply support member 43 according to change in a thickness of the driver mount portion GSd of the glass substrate GS, that is, change in a height position of the driver mount portion. For example, the height position of the outer plate surface (the rear side, on the opposite side from the driver 21) of the driver mount portion GSd is detected by a position detection sensor (not illustrated). The lifting/lowering speed of the substrate support member 41 and the driver-side heat supply support member 43 are determined based on the detection result. The height position of the outer plate surface of the driver mount portion GSd is lowered as the thickness of the driver mount portion GSd of the glass substrate GS is increased (thickened). The height position of the outer plate surface of the drover mount portion GSd is higher as the thickness of the driver mount portion GSd of the glass substrate GS is decreased (thinned).

The driver mounting apparatus 40 is in an initial state before moving the driver mount-side heat supply support member 42 and the driver-side heat supply support member 43. In the initial state, as illustrated in FIGS. 7 and 8, the driver mount-side heat supply support member 42 is away from the driver mount portion GSd of the glass substrate GS to be on a lower side in FIGS. 7 and 8 in the Z-axis direction with a certain distance therebetween. The driver-side heat supply support member 43 is away from the driver 21 to be on an upper side in FIGS. 7 and 8 in the Z-axis direction with a certain distance therebetween. Namely, in the initial state, the driver mount-side heat supply support member 42 and the driver-side heat supply support member 43 are not in contact with the driver mount portion GSd and the driver 21 and do not supply heat thereto. The driver mount-side heat supply support member 42 and the driver-side heat supply support member 43 are moved from the initial state to be in contact with the driver mount portion GSd and the driver 21, respectively, with a moving distance (relative moving amount). The moving distance of the driver-side heat supply support member 43 is relatively greater than the moving distance of the driver mount-side heat supply support member 42. The difference between the moving distances is substantially equal to a distance between the driver-side heat supply support member 43 and the driver 21 in the initial state. Therefore, in most cases, the movement control portion 46 controls the first moving portion 44 and the second moving portion 45 such that the moving speed (relative moving speed) of the driver-side heat supply support member 43 is greater than the moving speed of the driver mount-side heat supply support member 42.

Next, a method of manufacturing a liquid crystal panel (the array substrate 11b) with using the above-structured driver mounting apparatus 40 will be described. The method of manufacturing the liquid crystal panel 11 includes at least a structured components forming process, a substrate thinning process, a substrate bonding process, a polarizing plate attachment process, and a driver mounting process (mounting process). In the structured components forming process, metal films and insulation films are layered on an inner plate surface of each glass substrate GS of the CF substrate 11a and the array substrate 11b with the known photolithography method to form various structured components. In the substrate thinning process, the outer plate surface of the glass substrate GS on which the structured components are formed is subjected to etching to thin the glass substrate GS. In the substrate bonding process, the glass substrate GS of the CF substrate 11a and the glass substrate GS of the array substrate 11b are bonded together. In the polarizing plate attachment process, the polarizing plates 11f, 11g are attached to the respective outer plate surfaces of the glass substrates GS. In the driver mounting process (mounting process), the driver 21 is mounted on the drive mount portion GSd of the glass substrate GS included in the array substrate 11b with using the driver mounting apparatus 40. The driver mounting process further includes at least an anisotropic conductive film applying process, a provisional pressing process, and a pressing process. In the anisotropic conductive film applying process, the anisotropic conductive film 27 is applied on the driver mount portion GSd of the glass substrate GS included in the array substrate 11a. In the provisional pressing process, the driver 21 is placed on the anisotropic conductive film 27 and provisionally pressed. In the pressing process, the driver 21 is pressed. The method of manufacturing the liquid crystal panel 11 further includes a flexible printed circuit board mounting process where the flexible printed circuit board 13 is mounted on the liquid crystal panel 11. In the following, the substrate thinning process and the driver mounting process related to the array substrate 11b will be described in detail.

In the substrate thinning process, the glass substrate GS of the array substrate 11b is immersed in etching liquid for a certain period such that the outer plate surfaces are subjected to etching. The glass substrate GS subjected to etching has a thickness (a plate thickness) smaller than that before etching, and the thickness after etching is 0.1 mm to 0.15 mm. The thickness of the thinned glass substrate GS is smaller than that of the driver 21 (for example, 0.12 to 0.18 mm). The thinned glass substrate GS subjected to the substrate thinning process may have a constant thickness over an entire area within a plane surface thereof. However, the thickness may be uneven within the plane surface of the glass substrate GS. Mounting errors may be caused in the subsequent driver mounting process if the thickness of the driver mount portion GSd changes and is decreased or increased from the designed value.

In the anisotropic conductive film applying process included in the driver mounting process, the anisotropic conductive film 27 is applied on the driver mount portion GSd of the glass substrate GS included in the array substrate 11b. In the provisional pressing process included in the driver mounting process, the driver 21 is placed on the anisotropic conductive film 27 applied on the driver mount portion GSd and the driver 21 is provisionally pressed and fixed to the anisotropic conductive film 27. In the pressing process included in the driver mounting process, the driver mounting apparatus 40 illustrated in FIGS. 7 and 8 is used and the liquid crystal panel 11 including the polarizing plate 11f, 11g is placed on the substrate support member 41. In this state, the glass substrate GS included in the array substrate 11b is supported by the substrate support member 41 at the substrate main portion GSm from the rear side, and the polarizing plate 11g attached to the outer plate surface thereof is vacuum sucked by the substrate support member 41. Thus, the glass substrate GS is firmly held by the substrate support member 41. In the driver mounting apparatus 40 that is in the initial state, the movement control portion 46 controls driving of the first moving portion 44 and the second moving portion 45 such that the substrate support member 41 is lowered in the Z-axis direction and the driver-side heat supply support member 43 is lowered in the Z-axis direction. Accordingly, the driver mount portion GSd of the glass substrate GS supported by the substrate support member 41 is relatively moved to be closer to the driver mount-side heat supply support member 42, and the driver-side heat supply support member 43 is relatively moved to be closer to the driver 21.

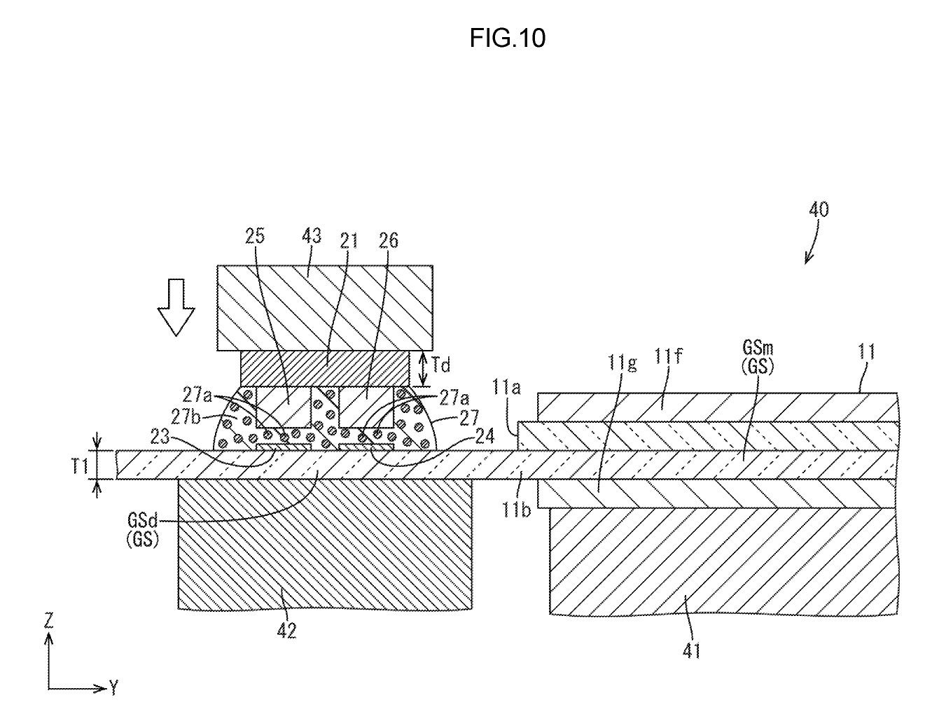

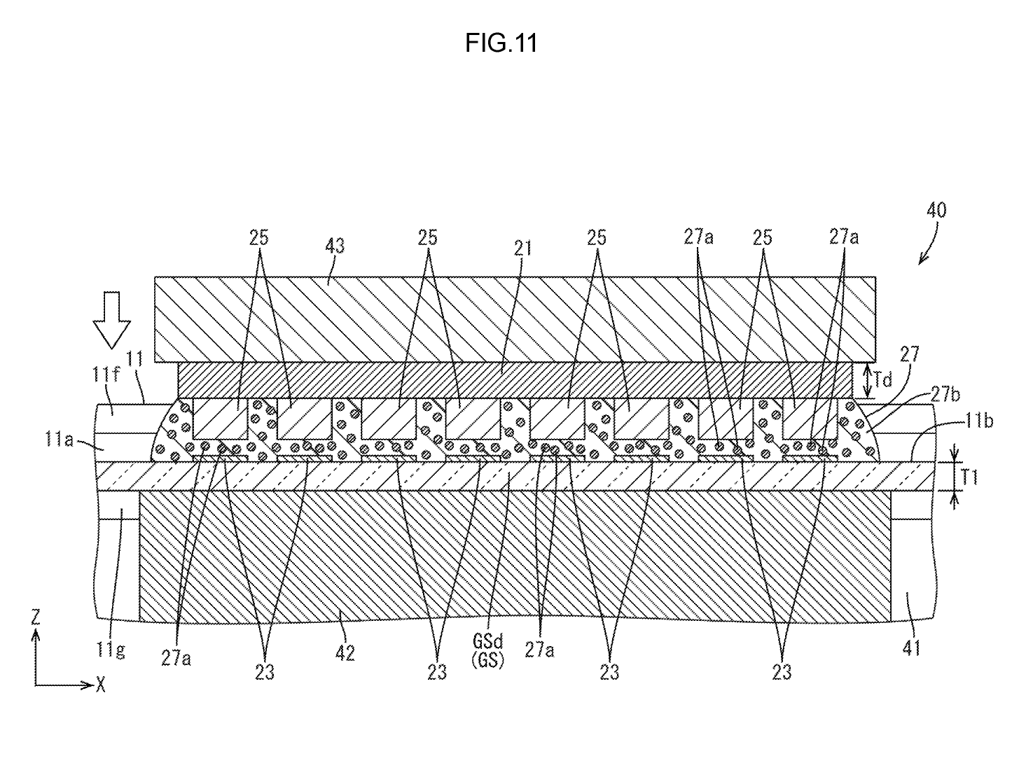

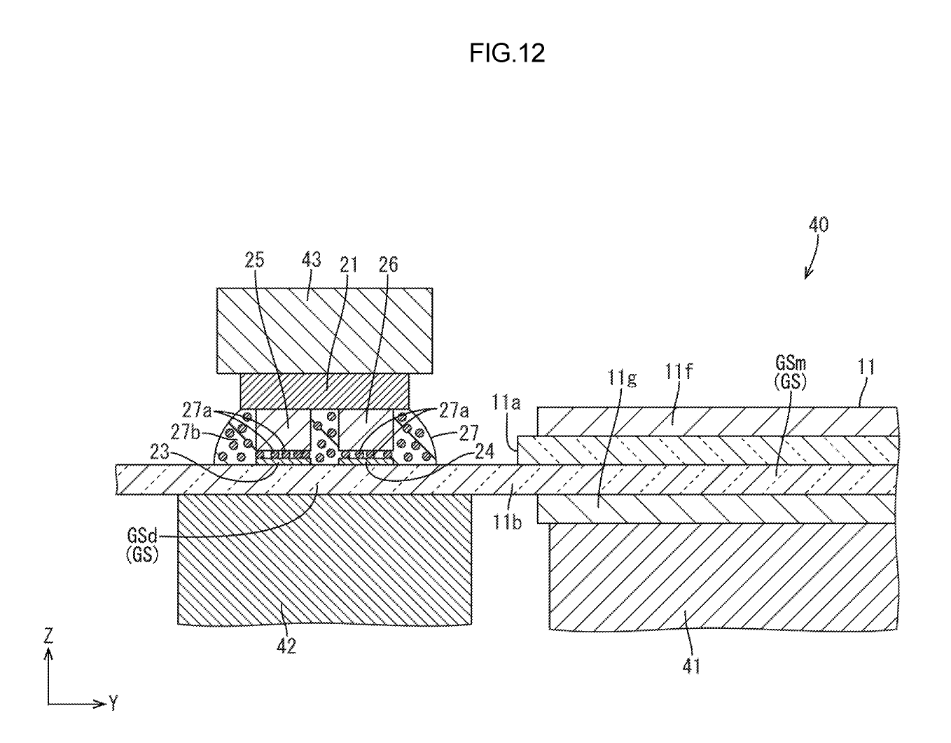

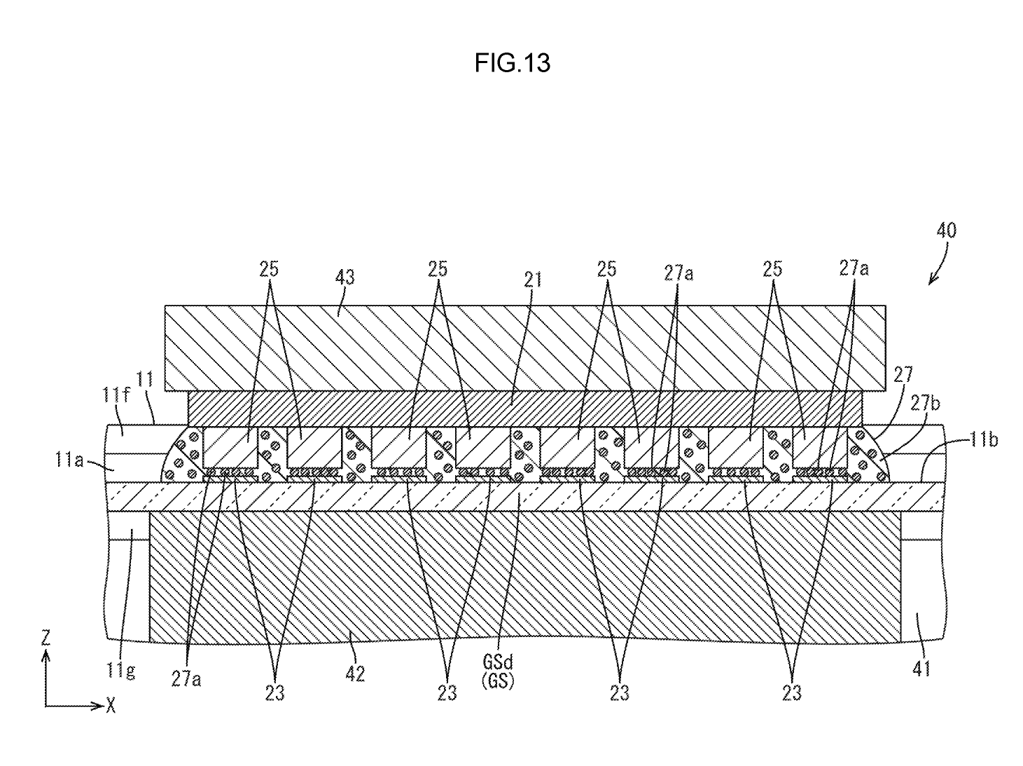

As illustrated in FIGS. 10 and 11, the driver mount portion GSd is in contact with the driver mount-side heat supply support member 42 and the driver-side heat supply support member 43 is in contact with the driver 21, and heat is supplied from the driver mount-side heat supply support member 42 to the driver mount portion GSd and heat is supplied from the driver-side heat supply support member 43 to the driver 21. The heat supplied to the driver mount portion GSd and the driver 21 from a contact start time is transferred to the thermosetting resin 27b of the anisotropic conductive film 27 and thermal curing of the thermosetting resin 27b is accelerated. In such a contact state, the lowering of the substrate support member 41 is stopped. However, the driver-side heat supply support member 43 is being lowered further and therefore, the driver 21, the driver mount portion GSd, and the anisotropic conductive film 27 therebetween are pressed. If the driver-side heat supply support member 43 reaches a certain height position, the lowering thereof is stopped and the pressing and the heat supplying are continued for a certain period. Accordingly, as illustrated in FIGS. 12 and 13, the terminals 25, 26 on the driver 21 side are electrically connected to the terminals 23, 24 on the array substrate 11b side via the conductive particles 27a contained in the anisotropic conductive film 27, and the thermosetting resin 27b included in the anisotropic conductive film 27 is thermally cured effectively and the driver 21 is pressed and fixed to the driver mount portion GSd. In the pressing process, the driver mount-side heat supply support member 42 and the driver-side heat supply support member 43 supply heat such that temperature of a connection surface of the terminals 25, 26 on the driver 21 side and the terminals 23, 24 on the array substrate 11b is 80° C. to 150° C. and apply a load of 100N to 450N to the driver mount portion GSd. After completion of the pressing, the movement control portion 46 controls the first moving portion 44 and the second moving portion 45 to lift the driver-side heat supply support member 43 in the Z-axis direction to be separated from the driver 21 and lift the substrate support member 41 in the Z-axis direction to be separated from the driver mount-side heat supply support member 42.

The glass substrate GS that is subjected to the substrate thinning process may have uneven thickness within a plane surface thereof, and the height position of the outer plate surface of the driver mount portion GSd may change. Therefore, in the pressing process included in the driver mounting process, the height position of the outer plate surface of the driver mount portion GSd is detected by the position detection sensor before moving the driver mount-side heat supply support member 42 and the driver-side heat supply support member 43. The movement control portion 46 controls the moving speed of the substrate support member 41 and the driver-side heat supply support member 43 moved by the first moving portion 44 and the second moving portion 45 based on the height position of the outer plate surface of the driver mount portion GSd detected by the position detection sensor. Accordingly, timing of contacting the driver mount-side heat supply support member 42 with the driver mount portion GSd and starting heat supply and timing of contacting the driver-side heat supply support member 43 with the driver 21 and starting heat supply are controlled. Hereinafter, means of setting the timing of starting heat supply according to the height position of the outer plate surface of the driver mount portion GSd will be described in detail.

If the thickness of the glass substrate GS is substantially constant over an entire area thereof and the thickness of the driver mount portion GSd is substantially a designed value, the timing of starting heat supply is determined as follows. As illustrated in FIGS. 7 and 8, thickness T1 of the driver mount portion GSd is smaller than thickness Td of the driver 21, and difference between the thickness T1 and the thickness Td is 0.02 mm to 0.03 mm. In this case, as illustrated in FIGS. 10 and 11, the movement control portion 46 controls the first moving portion 44 and the second moving portion 45 to control the moving speed of the substrate support member 41 and the driver-side heat supply support member 43 such that the timing of contacting the driver mount-side heat supply support member 42 with the driver mount portion GSd and starting heat supply and the timing of contacting the driver-side heat supply support member 43 with the driver 21 and starting heat supply are substantially same. In comparing the driver 21 and the glass substrate GS, the driver 21 is made of a silicon wafer containing high purity silicone and silicon has thermal conductivity of 168 W/(m·K) that is relatively high. The glass substrate is made of glass material, and the glass material has thermal conductivity of 0.55 W/(m·K) to 0.75 W/(m·K) that is relatively low. Therefore, the difference between the thermal conductivity of the driver 21 and the glass substrate GS is extremely great. The silicon of the driver 21 has linear expansion coefficient of 2.55·10−6/K to 4.33·10−6/K that is relatively low. The glass of the glass substrate GS has linear expansion coefficient of 4·10−⁺6/K to 8·10−6/K that is relatively high. The difference between the linear expansion coefficient is not so great as that of the thermal conductivity. As described before, the thickness Td of the driver is relatively great and the thickness of T1 of the driver mount portion GSd of the glass substrate GS is relatively small. Therefore, as described before, the timing of starting heat supply to the driver 21 and the driver mount portion GSd is substantially same so that difference is less likely to be caused between a thermal expansion/contraction amount of the driver 21 generated due to the heat supplied to the driver 21 and a thermal expansion/contraction amount of the driver 21 generated due to the heat supplied to the driver mount portion GSd. Further, difference is less likely to be caused between an amount of heat transferred to the thermosetting resin 27b contained in the anisotropic conductive film 27 via the driver 21 and an amount of heat transferred to the thermosetting resin 27b via the driver mount portion GSd. Accordingly, even if the glass substrate GS and the driver 21 are decreased in thickness, warpage that may be caused in mounting of the driver 21 is less likely to be caused.

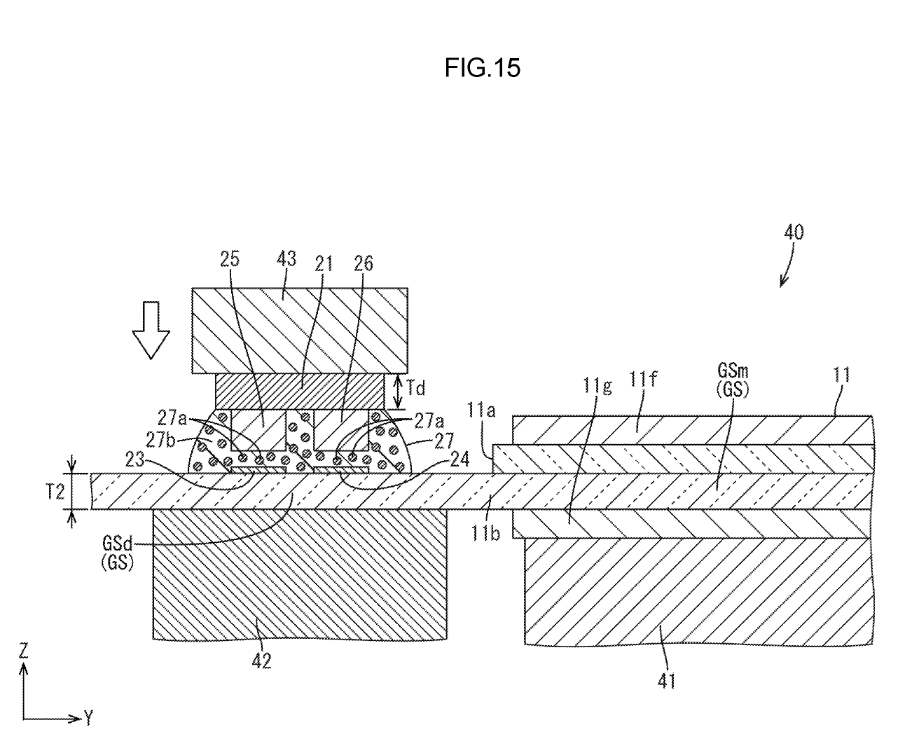

If the thickness of the glass substrate GS is uneven within a plane surface thereof and the thickness of the driver mount portion GSd is greater than the designed value and the thickness T2 of the driver mount portion GSd is same as the thickness Td of the driver 21, the timing of starting heat supply is determined as follows. In this case, the movement control portion 46 controls the first moving portion 44 and the second moving portion 45 to control the moving speed of the substrate support member 41 and the driver-side heat supply support member 43 such that the timing of contacting the driver mount-side heat supply support member 42 with the driver mount portion GSd and starting heat supply is prior to the timing of contacting the driver-side heat supply support member 43 with the driver 21 and starting heat supply. In comparing with the above case in which the timings of starting heat supply are same, the moving speed of the substrate support member 41 is relatively accelerated or the moving speed of the driver-side heat supply support member 43 is relatively reduced or both. As illustrated in FIG. 15, the driver-side heat supply support member 43 is in contact with the driver 21 after the driver mount-side heat supply support member 42 is in contact with the driver mount portion GSd. Accordingly, the heat is supplied to the driver mount portion GSd prior to the driver 21 and therefore, difference is less likely to be caused between the thermal expansion/contraction amount of the driver 21 and the thermal expansion/contraction amount of the driver mount portion GSd having relatively low thermal conductivity and the thickness T2 equal to the thickness Td of the driver 21. Further, difference is less likely to be caused between the amount of heat transferred to the thermosetting resin 27b contained in the anisotropic conductive film 27 via the driver 21 and the amount of heat transferred to the thermosetting resin 27b via the driver mount portion GSd. Accordingly, even if the thickness T2 of the driver mount portion Gsd is greater than the designed value and is same as the thickness Td of the driver 21, warpage that may be caused in mounting of the driver 21 is less likely to be caused.

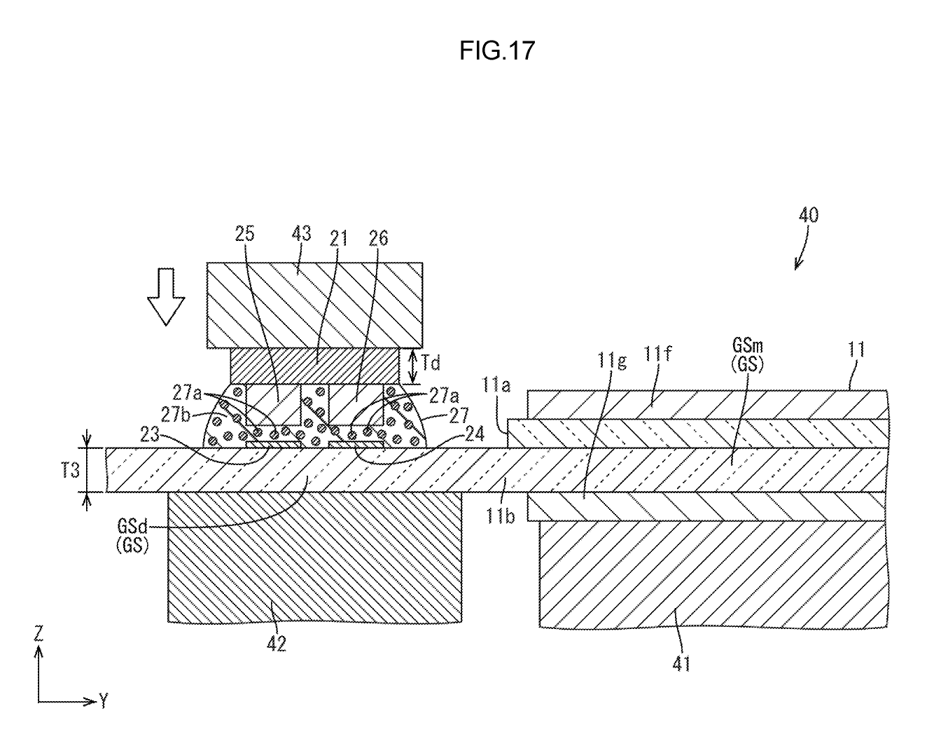

If the thickness of the glass substrate GS is uneven within a plane surface thereof and the thickness of the driver mount portion GSd is greater than the designed value and thickness T3 of the driver mount portion GSd is greater than the thickness Td of the driver 21, the timing of starting heat supply is determined as follows. In this case, the movement control portion 46 controls the first moving portion 44 and the second moving portion 45 to control the moving speed of the substrate support member 41 and the driver-side heat supply support member 43 such that the timing of contacting the driver mount-side heat supply support member 42 with the driver mount portion GSd and starting heat supply is prior to the timing of contacting the driver-side heat supply support member 43 with the driver 21 and starting heat supply, and time difference between the timings is greater than the time difference caused in the configuration that the thickness T2 of the driver mount portion GSd is same as the thickness Td of the driver. In comparing with the above case in which the thickness T2 of the driver mount portion GSd is greater than the thickness Td of the driver 21, the moving speed of the substrate support member 41 is relatively accelerated or the moving speed of the driver-side heat supply support member 43 is relatively reduced or both. As illustrated in FIG. 17, the driver-side heat supply support member 43 is in contact with the driver 21 after the driver mount-side heat supply support member 42 is in contact with the driver mount portion GSd. Accordingly, the heat is supplied to the driver mount portion GSd prior to the driver 21 and the amount of heat supplied to the driver mount portion GSd is greater than that in the configuration having the thickness T2 of the driver mount portion GSd being same as the thickness Td of the driver 21. Therefore, difference is less likely to be caused between the thermal expansion/contraction amount of the driver 21 and the thermal expansion/contraction amount of the driver mount portion GSd having relatively low thermal conductivity and the thickness T3 greater than the thickness Td of the driver 21. Further, difference is less likely to be caused between the amount of heat transferred to the thermosetting resin 27b contained in the anisotropic conductive film 27 via the driver 21 and the amount of heat transferred to the thermosetting resin 27b via the driver mount portion GSd. Accordingly, even if the thickness T3 of the driver mount portion GSd is greater than the designed value and is greater than the thickness Td of the driver 21, warpage that may be caused in mounting of the driver 21 is less likely to be caused.

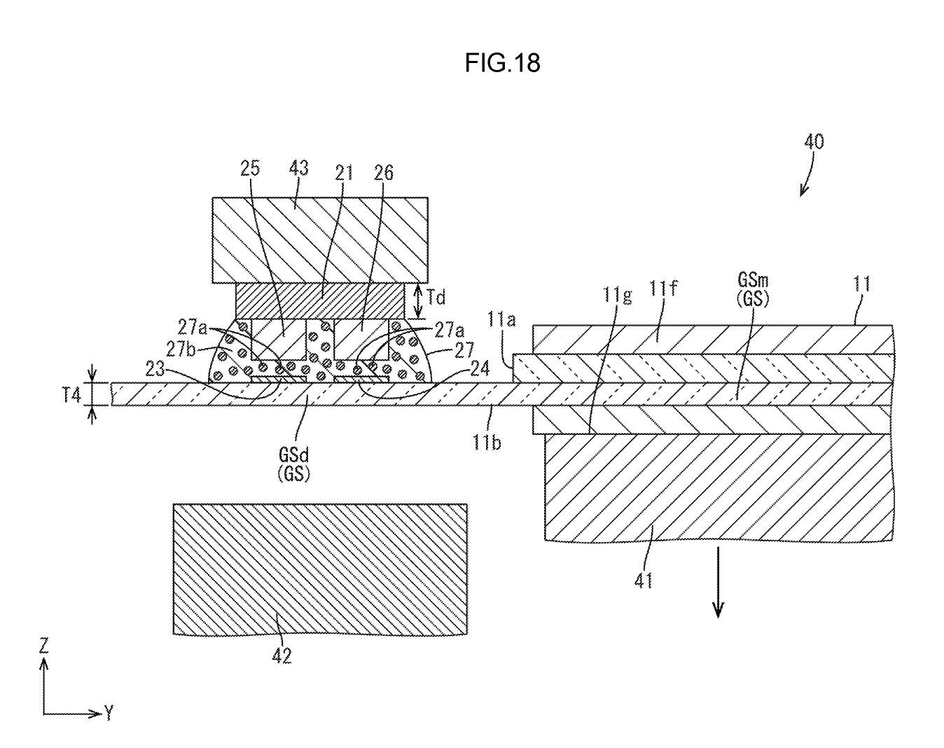

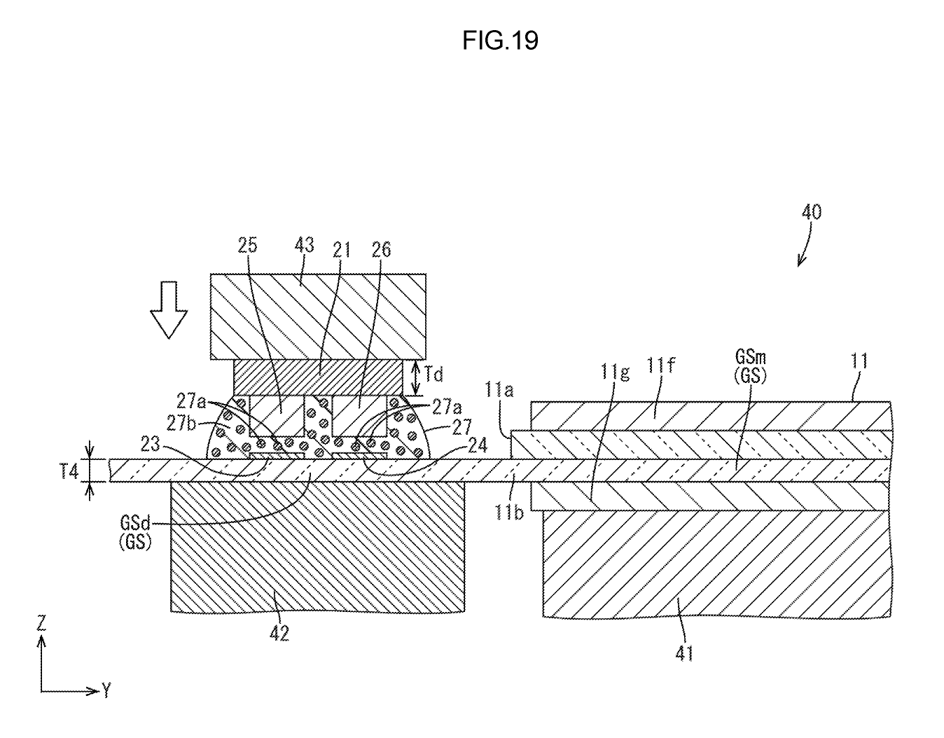

If the thickness of the glass substrate GS is uneven within a plane surface thereof and the thickness of the driver mount portion GSd is smaller than the designed value, the timing of starting heat supply is determined as follows. In this case, thickness T4 of the driver mount portion GSd is smaller than the thickness Td of the driver 21 and smaller than the thickness of the driver mount portion of the configuration that the thickness T1 of the driver mount portion is the designed value, as illustrated in FIG. 18. The difference is greater than 0.03 mm. The movement control portion 46 controls the first moving portion 44 and the second moving portion 45 to control the moving speed of the substrate support member 41 and the driver-side heat supply support member 43 such that the timing of contacting the driver mount-side heat supply support member 42 with the driver mount portion GSd and starting heat supply is after the timing of contacting the driver-side heat supply support member 43 with the driver 21 and starting heat supply. In comparing with the above case in which the timings of starting heat supply are same, the moving speed of the substrate support member 41 is relatively reduced or the moving speed of the driver-side heat supply support member 43 is relatively accelerated or both. As illustrated in FIG. 19, the driver mount-side heat supply support member 42 comes in contact with the driver mount portion GSd after the driver-side heat supply support member 43 is in contact with the driver 21. Accordingly, the heat is supplied to the driver 21 prior to the driver mount portion GSd and therefore, difference is less likely to be caused between the thermal expansion/contraction amount of the driver 21 and the thermal expansion/contraction amount of the driver mount portion GSd having relatively low thermal conductivity and the thickness T4 smaller than the thickness Td of the driver 21 and the designed value. Further, difference is less likely to be caused between the amount of heat transferred to the thermosetting resin 27b contained in the anisotropic conductive film 27 via the driver 21 and the amount of heat transferred to the thermosetting resin 27b via the driver mount portion GSd. Accordingly, even if the thickness T4 of the driver mount portion Gsd is smaller than the thickness Td of the driver 21 and smaller than the designed value, warpage that may be caused in mounting of the driver 21 is less likely to be caused.

The thickness of the driver mount portion GSd may not be as designed, if the thickness of the glass substrate GS is uneven within a plane surface thereof as described before. The thickness of the driver mount portion GSd may not be as designed, if the thickness of the glass substrate GS is greater or smaller than the designed value as a whole even with the thickness of the glass substrate GS being substantially same within the plane surface thereof. In such a case, the timings of starting heat supply may be controlled as described before.

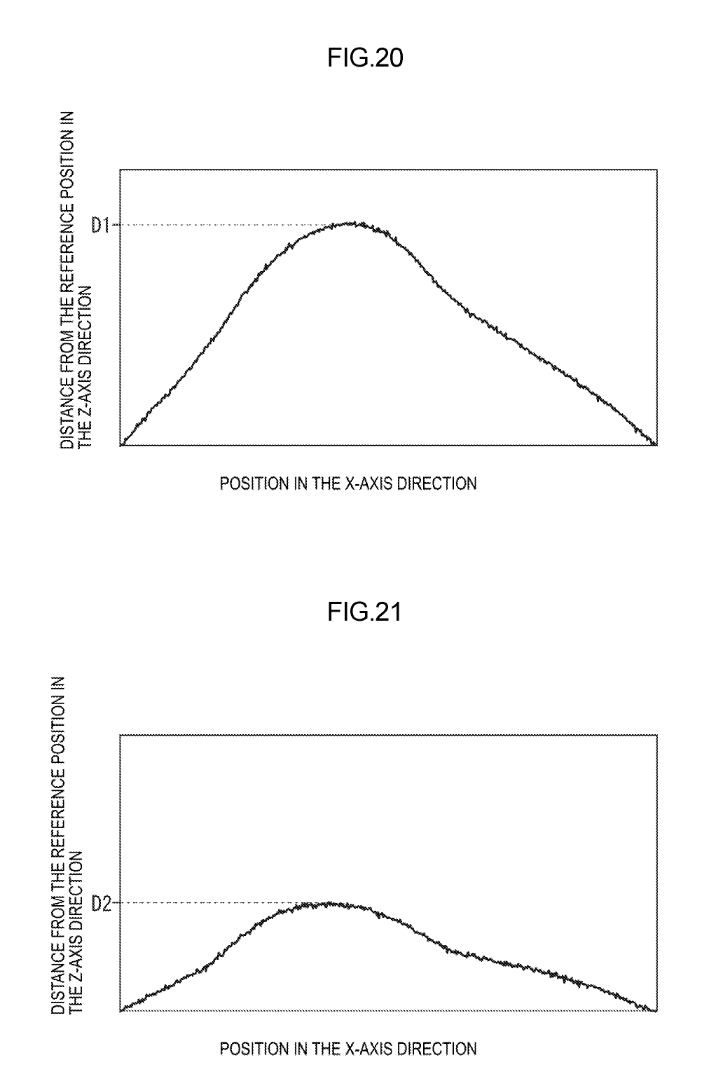

Comparative experiments have been carried out to know how the warpage of the glass substrate GS is less likely to be caused by executing the pressing process with using the driver mounting apparatus 40 of the present embodiment. In the Examples, the driver mounting apparatus 40 includes the substrate support member 41, the driver mount-side heat supply support member 42, the driver-side heat supply support member 43, the first moving portion 44, the second moving portion 45, and the movement control portion 46. In the Comparative Examples, a driver mounting device (not illustrated) includes a fixed substrate support member supporting the substrate main portion GSm of the glass substrate GS, a fixed driver mount-side supply support member supporting the driver mount portion GSd of the glass substrate GS without heating, and a movable heat pressing member that presses and heats the driver 21 from the front side. Warpage conditions of each glass substrate GS of the array substrates 11b that have been subjected to the pressing process with using the driver mounting devices of the Examples and the Comparative Examples were compared. The warpage condition of the glass substrate GS is measured as follows. A distance between the outer plate surface of the driver mount portion GSd of the glass substrate GS and a reference position in the Z-axis direction is measured. The warpage condition of the glass substrate GS is determined by detecting how the distance changes in different positions in the X-axis direction (the long-side direction of the driver 21). Specifically, the warpage is large as a maximum value of the distance and a rate of change in the distances are great, and the warpage is small as the maximum value and the rate of change are small. The distances were measured in a portion of the driver mount portion GSd overlapping the driver 21 in a plan view and over an area from one edge to another edge in the X-axis direction. The reference position in the Z-axis direction is a position in the Z-axis direction on a plate surface of the glass substrate GS outside the substrate main portion GSm or on a plate surface outside the portion of the driver mount portion GSd not overlapping the driver 21. FIGS. 20 and 21 illustrate results of comparative experiments. In FIGS. 20 and 21, a vertical axis represents a distance (no unit) from the reference position to the plate surface outside the driver mount portion GSd in the Z-axis direction, and a horizontal axis represents a position (no unit) in the X-axis direction. The vertical axis and the horizontal axis have a same scale in FIGS. 20 and 21.

The results of the comparative experiments will be described. According to the results in FIGS. 20 and 21, a maximum value D1 of the distance with using the driver mounting apparatus of the Comparative Example and a maximum value D2 of the distance with using the driver mounting apparatus 40 of the Example were compared. According to the comparison, the maximum value D2 is smaller than the maximum value D1 and specifically, the maximum value D2 is approximately a half of the maximum value D1. It is confirmed that the warpage generated in the driver mounting apparatus 40 is small.

As described before, the driver mounting apparatus (manufacturing apparatus) 40 for mounting the array substrate (the mounting substrate) 11b of the present embodiment includes the driver mount-side heat supply support member (the component mount-side heat supply support member) 42, the substrate support member 41, the driver-side heat supply support member (the mounting component-side heat supply support member) 43, the first moving portion 44, and the second moving portion 45. The driver mount-side heat supply support member 42 is arranged on an opposite side from the driver 21 with respect to the glass substrate (the substrate) GS where the driver (the component) is mounted. The driver mount-side heat supply support member 42 supports the driver mount portion (the component mount portion) GSd of the glass substrate GS and supplies heat to the driver mount portion GSd where the driver 21 is mounted. The substrate support member 41 is arranged on the same side with the driver mount-side heat supply support member 42 with respect to the glass substrate GS, and supports the substrate main portion GSm of the glass substrate GS except for the driver mount portion GSd. The driver-side heat supply support member 43 is arranged on the opposite side from the driver mount portion GSd with respect to the driver 21. The driver-side heat supply support member 43 and the driver mount-side heat supply support member 42, which supports the driver mount portion GSd, sandwich the driver 21 therebetween to support it and supplies heat to the driver 21. The first moving portion 44 relatively moves the driver mount portion GSd and the driver mount-side heat supply support member 42 in the overlapping direction in which the glass substrate GS and the driver 21 are overlapped. The second moving portion 45 relatively moves the driver 21 and the driver-side heat supply support member 43 in the overlapping direction.

The driver 21 is mounted on the glass substrate GS as follows. The substrate main portion GSm of the glass substrate GS except for the driver mount portion GSd is supported by the substrate support member 41 that is arranged on an opposite side from the driver 21 with respect to the glass substrate GS. The driver mount portion GSd and the driver mount-side heat supply support member 42, which is arranged on the opposite side from the driver 21 with respect to the glass substrate GS, are moved relatively closer to each other by the first moving portion 44 in the overlapping direction in which the glass substrate GS and the driver 21 are overlapped. Further, the driver 21 and the driver-side heat supply support member 43, which is arranged on the opposite side from the driver mount portion GSd with respect to the driver 21, are moved relatively closer to each other by the second moving portion 45 in the overlapping direction. The driver-side heat supply support member 43 and the driver mount-side heat supply support member 42 sandwich the driver 21 and the driver mount portion GSd therebetween and press the driver 21 and the driver mount portion GSd. The driver mount-side heat supply support member 42 supplies heat to the driver mount portion GSd and the driver-side heat supply support member 43 supplies heat to the driver 21. Thus, the driver 21 is mounted on the glass substrate GS.

Thus, the driver mount-side heat supply support member 42 and the driver-side heat supply support member 43 are relatively movable by the first moving portion 44 and the second moving portion 45, respectively. Therefore, the timing of contacting the driver mount-side heat supply support member 42 with the driver mount portion GSd and starting heat supply and the timing of contacting the driver-side heat supply support member 43 with the driver 21 and starting heat supply are freely determined. Therefore, even if the thickness of the driver mount portion GSd of the glass substrate GS and the thickness of the driver 21 may vary due to the manufacturing matters, unevenness in heating and pressing caused due to the variation of the thicknesses is less likely to be caused and connection errors are less likely to occur by adjusting the timings of starting heat supply by the first moving portion 44 and the second moving portion 45. Further, even if difference in the thermal conductivity is caused due to the difference in the material of the driver 21 and the glass substrate GS, the difference between the thermal expansion/shrinkage amounts of the glass substrate GS and the driver 21 having different thermal conductivity is reduced by adjusting the timings of starting heat supply by the first moving portion 44 and the second moving portion 45. Accordingly, warpage that may be caused by mounting of the driver 21 is less likely to occur with the glass substrate GS and the driver 21 being thinned. Further, if the positions of the substrate support member 41 and the driver mount-side heat supply support member 42 are fixed in the overlapping direction, the driver mount-side heat supply support member 42 continues supplying heat to the driver mount portion GSd until the driver-side heat supply support member 43 starts pressing of the driver 21 and therefore, connection errors may occur. However, such errors are obviated by adjusting the timings of starting heat supply by the first moving portion 44 and the second moving portion 45. Thus, the contact errors are less likely to occur and warpage is less likely to be caused.

The driver mounting apparatus further includes the movement control portion 46 that controls the first moving portion 44 to control relative moving speed of the driver mount portion GSd relative to the driver mount-side heat supply support member 42 and controls the second moving portion 45 to control relative moving speed of the driver-side heat supply support member 43 relative to the driver 21. Accordingly, the movement control portion 46 controls the first moving portion 44 and the second moving portion 45 to control relative moving speed of the driver mount portion GSd relative to the driver mount-side heat supply support member 42 and control relative moving speed of the driver-side heat supply support member 43 relative to the driver 21 to set appropriate timing of starting heat supply to the driver mount portion GSd and the driver 21. Comparing to the configuration that the relative moving speed is fixed and the position of the driver mount portion GSd and the driver mount-side heat supply support member 42 and the position of the driver 21 and the driver-side heat supply support member 43 are adjusted, respectively, the configuration of the driver mounting apparatus 40 is less likely to be complicated and the driver mounting apparatus 40 is effectively reduced in size.

The movement control portion 46 controls the first moving portion 44 and the second moving portion 45 such that the timing of contacting the driver mount-side heat supply support member 42 with the driver mount portion GSd and the timing of contacting the driver-side heat supply support member 43 with the driver 21 are same. Accordingly, for example, if the glass substrate GS having thermal conductivity lower than that of the driver 21 is thinner than the driver 21, the thermal expansion/contraction amounts of the glass substrate GS and the driver 21 are effectively equalized.

The movement control portion 46 controls the first moving portion 44 and the second moving portion 45 such that the timing of contacting the driver mount-side heat supply support member 42 with the driver mount portion GSd is prior to the timing of contacting the driver-side heat supply support member 43 with the driver 21. Accordingly, for example, if the glass substrate GS having thermal conductivity lower than that of the driver 21 has substantially same thickness as that of the driver 21 or is thicker than the driver 21, the thermal expansion/contraction amounts of the glass substrate GS and the driver 21 are effectively equalized.

The movement control portion 46 controls the first moving portion 44 and the second moving portion 45 such that the timing of contacting the driver mount-side heat supply support member 42 with the driver mount portion GSd is after the timing of contacting the driver-side heat supply support member 43 with the driver 21. Accordingly, for example, if the glass substrate GS having thermal conductivity lower than that of the driver 21 is thinner than the driver 21 and the thickness difference is quite large, the thermal expansion/contraction amounts of the glass substrate GS and the driver 21 are effectively equalized.

The position of the driver mount-side heat supply support member 42 is fixed in the overlapping direction. The first moving portion 44 moves the substrate support member 41 to relatively move the driver mount portion GSd of the glass substrate GS supported by the substrate support member 41 with respect to the driver mount-side heat supply support member 42. The second moving portion 45 moves the driver-side heat supply support member 43 to relatively move the driver-side heat supply support member 43 with respect to the driver 21. The glass substrate GS includes the driver mount portion GSd and the substrate main portion GSm that is supported by the substrate support member 41, and the driver mount portion GSd is relatively moved to be closer to the driver mount-side heat supply support member 42 that is fixed in the overlapping direction, as the first moving portion 44 moves the substrate support member 41. The driver-side heat supply support member 43 is relatively moved to be closer to the driver 21 as being moved by the second moving portion 45. Thus, the position of the driver mount-side heat supply support member 42 is fixed in the overlapping direction as is in the previous apparatus. Therefore, a cost for changing the configuration of the previous driver mounting apparatus 40 is maintained low.

The method of manufacturing the array substrate 11b according to the present embodiment includes the provisional pressing process and the pressing process. In the provisional pressing process, the driver 21 is provisionally pressed and mounted on the glass substrate GS. In the pressing process, the following processes are executed. The substrate main portion GSm of the glass substrate GS except for the driver mount portion GSd where the driver 21 is mounted is supported by the substrate support member 41 that is arranged on the opposite side from the driver 21 with respect to the glass substrate GS where the driver 21 is mounted. The driver mount portion GSd and the driver mount-side heat supply support member 42 that is arranged on the same side with the substrate support member 41 with respect to the glass substrate GS are relatively moved by the first moving portion 44 in the overlapping direction in which the glass substrate GS and the driver 21 are overlapped. The driver 21 and the driver-side heat supply support member 43 that is arranged on the opposite side from the driver mount-side heat supply support member 42 with respect to the glass substrate GS are relatively moved by the second moving portion 45 in the overlapping direction. The driver mount-side heat supply support member 42 is in contact with and supports the driver mount portion GSd and supplies heat to the driver mount portion GSd. The driver-side heat supply support member 43 is in contact with and supports the driver 21 and supplies heat to the driver 21. Thus, the driver 21 is pressed and mounted on the glass substrate GS.

The driver 21 that is provisionally pressed and mounted on the glass substrate GS in the provisional pressing process is mounted on the glass substrate GS as follows. The substrate main portion GSm of the glass substrate GS except for the driver mount portion GSd is supported by the substrate support member 41 that is arranged on the opposite side from the driver 21 with respect to the glass substrate GS. The driver mount portion GSd and the driver mount-side heat supply support member 42 that is arranged on the opposite side from the driver 21 with respect to the glass substrate GS is relatively moved to be closer to each other by the first moving portion 44 in the overlapping direction in which the glass substrate GS and the driver 21 are overlapped. The driver 21 and the driver-side heat supply support member 43 that is arranged on the opposite side from the driver amount portion GSd with respect to the driver 21 are relatively moved to be closer to each other by the second moving portion 45 in the overlapping direction. The driver-side heat supply support member 43 and the driver mount-side heat supply support member 42 sandwich the driver 21 and the driver mount portion GSd therebetween and press them. The driver mount-side heat supply support member 42 supplies heat to the driver mount portion GSd with pressing and the driver-side heat supply support member 43 supplies heat to the driver 21 with pressing. Thus, the driver 21 is mounted on the glass substrate GS.

Thus, the driver mount-side heat supply support member 42 and the driver-side heat supply support member 43 are relatively movable by the first moving portion 44 and the second moving portion 45, respectively. Therefore, the timing of contacting the driver mount-side heat supply support member 42 with the driver mount portion GSd and starting heat supply and the timing of contacting the driver-side heat supply support member 43 with the driver 21 and starting heat supply are freely determined. Therefore, even if the thickness of the driver mount portion GSd of the glass substrate GS and the thickness of the driver 21 may vary due to the manufacturing matters, unevenness in heating and pressing caused due to the variation of the thicknesses is less likely to be caused and connection errors are less likely to occur by adjusting the timings of starting heat supply by the first moving portion 44 and the second moving portion 45. Further, even if difference in the thermal conductivity is caused due to the difference in the material of the driver 21 and the glass substrate GS, the difference between the thermal expansion/shrinkage amounts of the glass substrate GS and the driver 21 having different thermal conductivity is reduced by adjusting the timings of starting heat supply by the first moving portion 44 and the second moving portion 45. Accordingly, warpage that may be caused by mounting of the driver 21 is less likely to occur with the glass substrate GS and the driver 21 being thinned. Further, if the positions of the substrate support member 41 and the driver mount-side heat supply support member 42 are fixed in the overlapping direction, the driver mount-side heat supply support member 42 continues supplying heat to the driver mount portion GSd until the driver-side heat supply support member 43 starts pressing of the driver 21 and therefore, connection errors may occur. However, such errors are obviated by adjusting the timings of starting heat supply by the first moving portion 44 and the second moving portion 45. Thus, the connection errors are less likely to occur and warpage is less likely to be caused.

In the pressing process, the movement control portion 46 controls the first moving portion 44 to control relative moving speed of the driver mount portion GSd relative to the driver mount-side heat supply support member 42 and controls the second moving portion 45 to control relative moving speed of the driver-side heat supply support member 43 relative to the driver 21. Accordingly, the movement control portion 46 controls the first moving portion 44 and the second moving portion 45 to control relative moving speed of the driver mount portion GSd relative to the driver mount-side heat supply support member 42 and control relative moving speed of the driver-side heat supply support member 43 relative to the driver 21 to set appropriate timing of starting heat supply to the driver mount portion GSd and the driver 21. Comparing to the configuration that the relative moving speed is fixed and the position of the driver mount portion GSd and the driver mount-side heat supply support member 42 and the position of the driver 21 and the driver-side heat supply support member 43 are adjusted, respectively, the configuration of the driver mounting apparatus 40 is less likely to be complicated and the driver mounting apparatus 40 is effectively reduced in size.

In the pressing process, the movement control portion 46 controls the first moving portion 44 and the second moving portion 45 such that the timing of contacting the driver mount-side heat supply support member 42 with the driver mount portion GSd and the timing of contacting the driver-side heat supply support member 43 with the driver 21 are same. Accordingly, for example, if the glass substrate GS having thermal conductivity lower than that of the driver 21 is thinner than the driver 21, the thermal expansion/contraction amounts of the glass substrate GS and the driver 21 are effectively equalized.

In the pressing process, the movement control portion 46 controls the first moving portion 44 and the second moving portion 45 such that the timing of contacting the driver mount-side heat supply support member 42 with the driver mount portion GSd is prior to the timing of contacting the driver-side heat supply support member 43 with the driver 21. Accordingly, for example, if the glass substrate GS having thermal conductivity lower than that of the driver 21 has substantially same thickness as that of the driver or is thicker than the driver 21, the thermal expansion/contraction amounts of the glass substrate GS and the driver 21 are effectively equalized.

In the pressing process, the movement control portion 46 controls the first moving portion 44 and the second moving portion 45 such that the timing of contacting the driver mount-side heat supply support member 42 with the driver mount portion GSd is after the timing of contacting the driver-side heat supply support member 43 with the driver 21. Accordingly, for example, if the glass substrate GS having thermal conductivity lower than that of the driver 21 is thinner than the driver 21 and the thickness difference is quite large, the thermal expansion/contraction amounts of the glass substrate GS and the driver 21 are effectively equalized.

### Second Embodiment

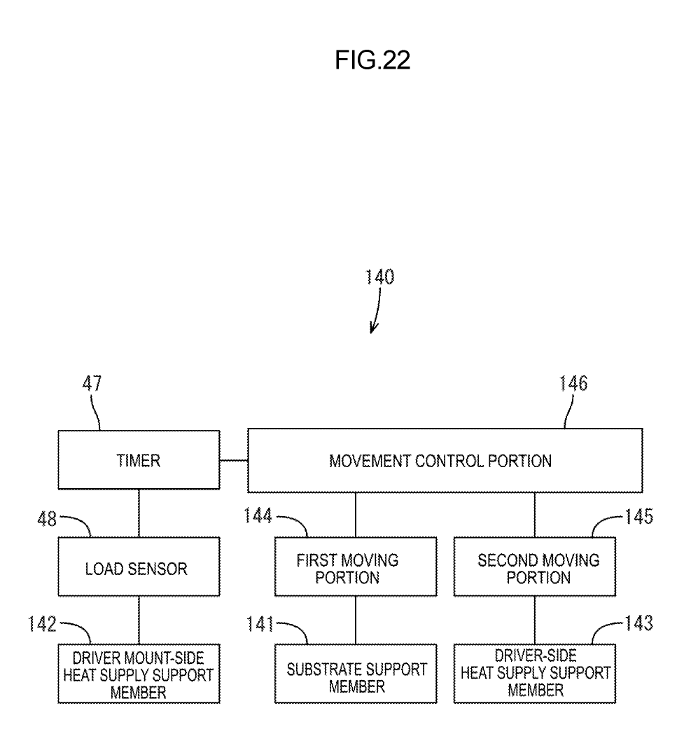

A second embodiment of the present invention will be described with reference to FIGS. 22 to 24. In the second embodiment, a driver-side heat supply support member 143 is moved based on time that has passed after a driver mount-side heat supply support member 142 is in contact with the driver mount portion GSd. Configurations, operations, and effects similar to those in the first embodiment will not be described.

As illustrated in FIG. 22, a driver mounting apparatus 140 according to the present embodiment includes a timer 47 and a load sensor 48. The timer 47 counts time that has passed after the driver mount-side heat supply support member 142 is in contact with the driver mount portion GSd of the glass substrate GS. The load sensor 48 detects load acting when the driver mount portion GSd is in contact with the driver mount-side heat supply support member 142. A movement control portion 146 controls a first moving portion 144 and a second moving portion 145 such that the timing of contacting the driver mount-side heat supply support member 142 with the driver mount portion GSd is prior to the timing of contacting the driver-side heat supply support member 143 with a driver 121. Thus, the moving speed of a substrate support member 141 and the driver-side heat supply support member 143 are adjusted and the timer 47 and the load sensor 48 are used and the operations of the timer 47 and the load sensor 48 will be described below.

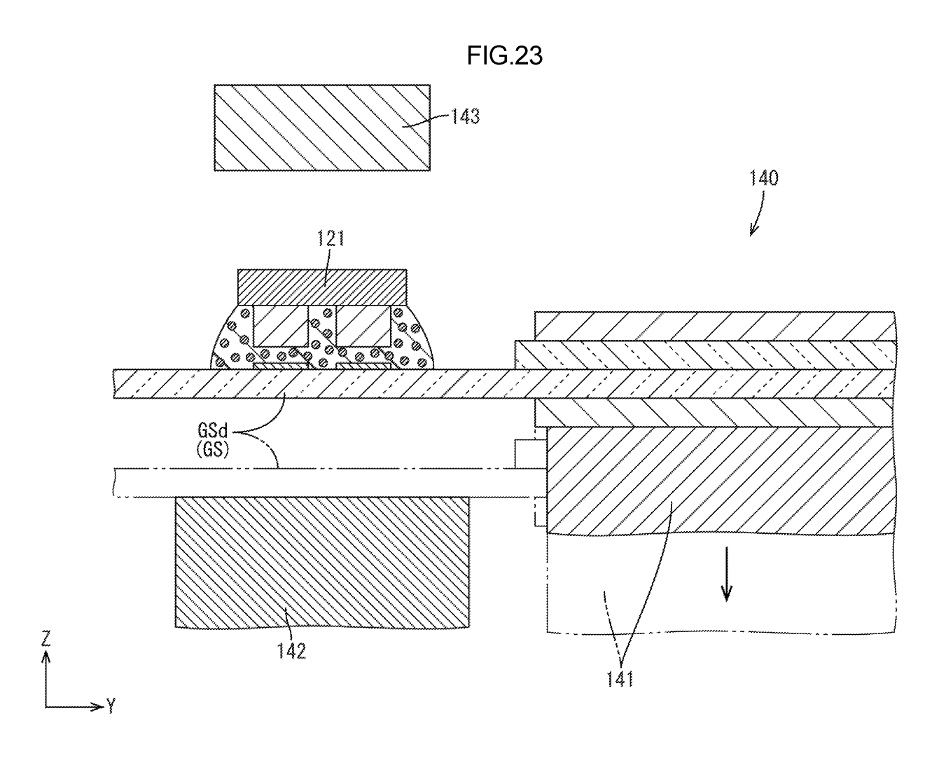

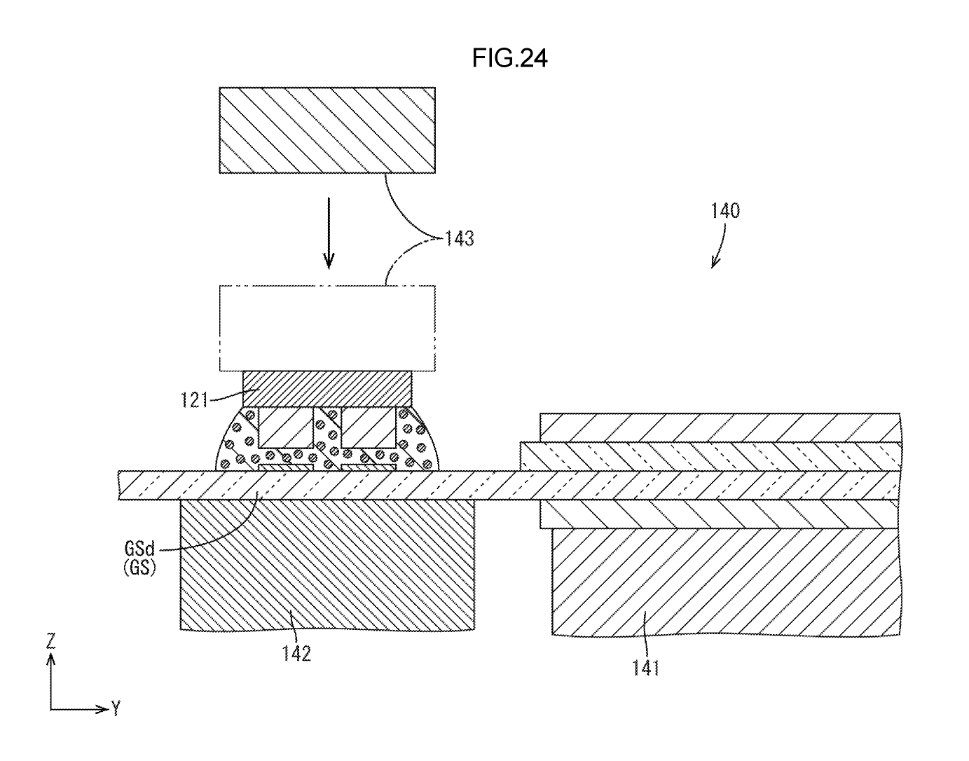

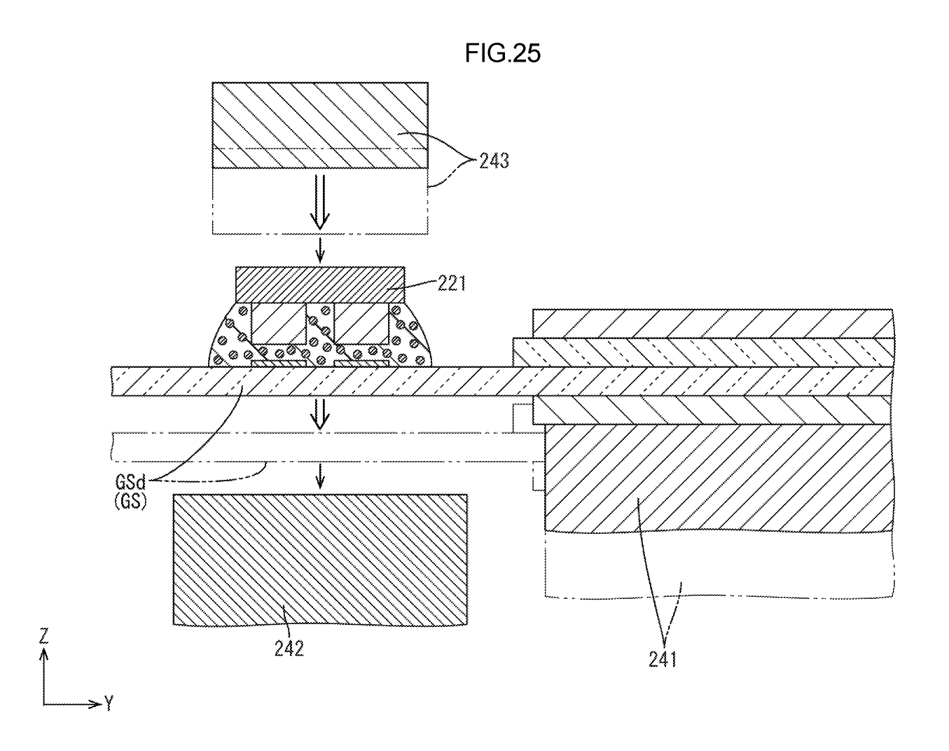

As illustrated in FIG. 23, the driver-side heat supply support member 143 is not moved until a predetermined time passes after the driver mount-side heat supply support member 142 is first in contact with the driver mount portion GSd. As illustrated in FIG. 22, the load sensor 48 detects load acting when the driver mount-side heat supply support member 142 is in contact with the driver mount portion GSd. If the load is detected by the load sensor 48, the timer 47 starts to count time and the counted time matches elapsed time after the contact of the driver mount-side heat supply support member 142 and the driver mount portion GSd. If the counted time counted by the timer 47 reaches the predetermined time, the movement control portion 146 controls the second moving portion 145 to lower the driver-side heat supply support member 143 in the Z-axis direction to relatively move closer to the driver 21, as illustrated in FIGS. 22 and 24. Accordingly, the driver-side heat supply support member 143 starts to supply heat to the driver 21 after a certain amount of heat is supplied from the driver mount-side heat supply support member 142 to the driver mount portion GSd. Therefore, the thermal expansion/contraction amounts of the glass substrate GS and the driver 121 are effectively equalized even with the variation of thicknesses of the driver mount portion GSd. The substrate support member 141 and the glass substrate GS after moving are described by two-dot chain lines in FIG. 23, and the driver-side heat supply support member 143 after moving is described by two-dot chain line in FIG. 24.

As described before, according to the present embodiment, the timer 47 counts time that has passed after the driver mount-side heat supply support member 142 is in contact with the driver mount portion GSd of the glass substrate GS. If the counted time counted by the timer 47 reaches the predetermined time, the movement control portion 146 controls the second moving portion 145 to start relative movement of the driver 121 and the driver-side heat supply support member 143 to be closer to each other. Accordingly, when the driver mount-side heat supply support member 142 is first in contact with the driver mount portion GSd and supplies heat thereto, the timer 47 counts time that has passed after the contact of the driver mount-side heat supply support member 142 and the driver mount portion GSd. The relative movement of the driver 121 and the driver-side heat supply support member 143 to be closer to each other is started by the second moving portion 145 if the counted time reaches the predetermined time. The driver-side heat supply support member 143 starts to supply heat to the driver 21 after a certain amount of heat is supplied from the driver mount-side heat supply support member 142 to the driver mount portion GSd. Therefore, the thermal expansion/contraction amounts of the glass substrate GS and the driver 121 are effectively equalized.

### Third Embodiment

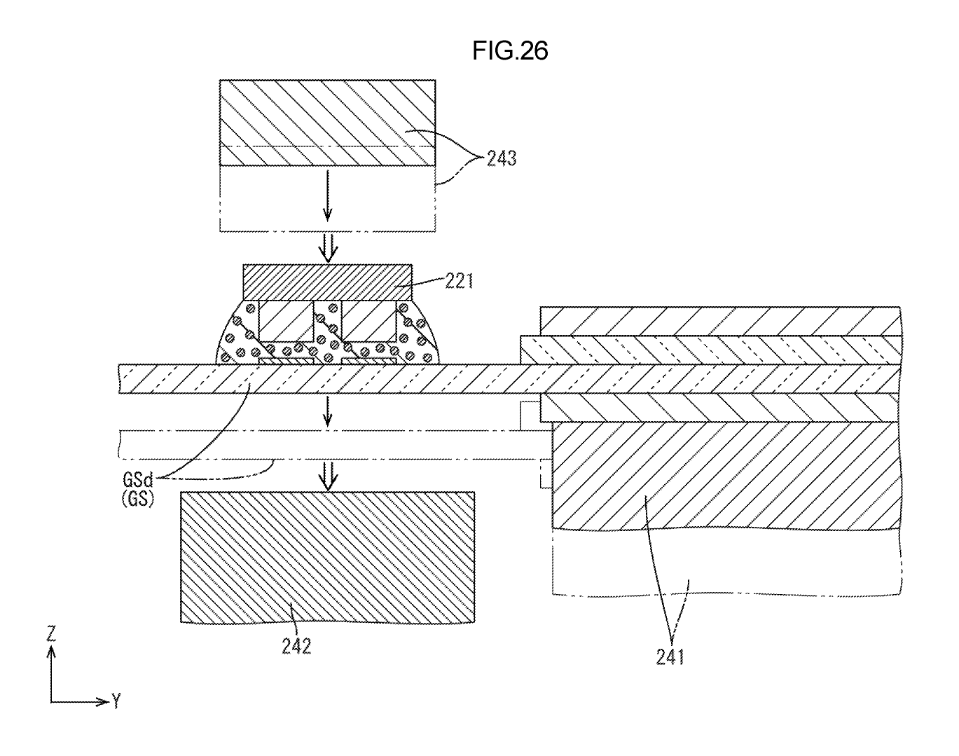

A third embodiment of the present invention will be described with reference to FIGS. 25 and 26. According to the third embodiment, moving speed of a substrate support member 241 and a driver-side heat supply support member 243 are changed during the movement thereof in the configuration of the first embodiment. Configurations, operations, and effects similar to those in the first embodiment will not be described.

As illustrated in FIG. 25, a movement control portion according to the present embodiment controls a first moving portion and a second moving portion such that moving speed of the substrate support member 241 and moving speed of the driver-side heat supply support member 243 are changed during a period after the substrate support member 241 and the driver-side heat supply support member 243 start to be lowered (move, relatively move) in the Z-axis direction from an initial state and until the lowering is completed. Specifically, the movement control portion may control the moving speed of the substrate support member 241 and the moving speed of the driver-side heat supply support member 243 to be relatively fast for a while from the initial state and then controlled to be relatively slow until completion of the lowering (completion of moving, completion of relative moving). The moving speed may be controlled to be relatively slow for a while from the initial state and then controlled to be relatively fast until the completion of the lowering as illustrated in FIG. 26. Accordingly, the timings described below may be determined freely and appropriately. The timings include timing of starting moving the substrate support member 241 from the initial state, timing of contacting the driver-side heat supply support member 243 with the driver 221, and timing of contacting a driver mount-side heat supply support member 242 with the driver mount portion GSd. Especially, as illustrated in FIG. 25, the moving speed of the substrate support member 241 and the driver-side heat supply support member 243 is set relatively slow from an intermediate timing to the completion of the lowering (the completion of moving, the completion of relative moving), and accordingly, shock that may be caused when the driver-side heat supply support member 243 is contacted with the driver 221 and when the driver mount-side heat supply support member 242 is contacted with the driver mount portion GSd of the glass substrate GS may be reduced and the driver 221 and the driver mount portion GSd are less likely to be damaged. In FIGS. 25 and 26, the substrate support member 241, the glass substrate GS, and the driver-side heat supply support member 243 that change moving speed during moving are described by two dot lines and thick arrows represent relatively fast speed and thin arrows represent relatively slow speed.

As described before, according to the present embodiment, the movement control portion controls the first moving portion and the second moving portion such that the relative moving speed of the driver mount portion GSd and the driver mount-side heat supply support member 242 and the relative moving speed of the driver 221 and the driver-side heat supply support member 243 are changed at the intermediate timing. Accordingly, the timings described below are determined appropriately according to the position of the driver mount portion GSd and the driver mount-side heat supply support member 242 and the position of the driver 221 and the driver-side heat supply support member 243. The timings include the timing of contacting the driver mount-side heat supply support member 242 with the driver mount portion GSd and the timing of contacting the driver-side heat supply support member 243 with the driver 221. Further, for example, the relative moving speed is set fast for a while from the starting of the mounting and set slow from the intermediate timing to the end such that shock that may be caused when the driver-side heat supply support member 243 is contacted with the driver 221 and when the driver mount-side heat supply support member 242 is contacted with the driver mount portion GSd may be reduced.

### Fourth Embodiment

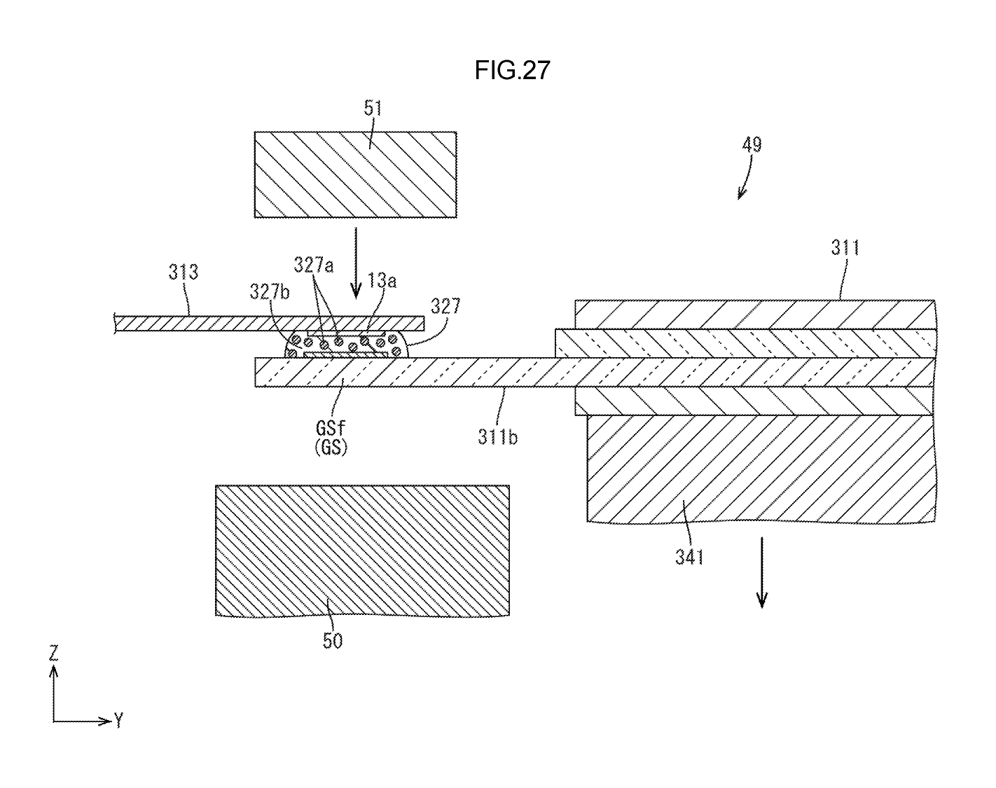

A fourth embodiment of the present invention will be described with reference to FIG. 27. In the fourth embodiment, a flexible printed circuit board mounting apparatus 49 is described. The flexible printed circuit board mounting apparatus 49 is used to mount a flexible printed circuit board 313 on a liquid crystal panel 311. Configurations, operations, and effects similar to those in the first embodiment will not be described.

As is described in the first embodiment, as illustrated in FIG. 27, the flexible printed circuit board 313 (the component) is mounted on an edge portion of an array substrate 311b of the liquid crystal panel 311 (see FIG. 4) and is electrically connected to external connection terminals 322 via conductive particles 327a contained in an anisotropic conductive film 327. The flexible printed circuit board 313 includes flexible board-side terminals 13a on an edge portion of a film substrate closer to the liquid crystal panel 311. The flexible board-side terminals 13a are arranged linearly at a predetermined interval in the X-axis direction similarly to the external connection terminals 322.

The flexible printed circuit board mounting apparatus 49 illustrated in FIG. 27 is used in a flexible printed circuit board mounting process of mounting the flexible printed circuit board 313 on the liquid crystal panel 311. The flexible printed circuit board mounting apparatus 49 includes a substrate support member 341, a flexible board mount-side heat supply support member (a component mount-side heat supply support member) 50, and a flexible board-side heat supply support member (a mounting component-side heat supply support member) 51. The substrate support member 341 supports the substrate main portion GSm of the glass substrate GS included in the array substrate 311b from a rear side. The flexible board mount-side heat supply support member 50 supports from a rear side a flexible board mount portion (a component mount portion) GSf of the glass substrate GS where the flexible printed circuit board 313 is mounted and supplies heat to the flexible board mount portion GSf. The flexible board-side heat supply support member 51 supports the flexible printed circuit board 313 from a front side and supplies heat to the flexible printed circuit board 313. The flexible board-side heat supply support member 51 is lifted and lowered by a second moving portion, which is not illustrated, in the Z-axis direction. The flexible board mount-side heat supply support member 50 and the flexible board-side heat supply support member 51 have configurations same as those of the driver mount-side heat supply support member 42 and the driver-side heat supply support member 43 of the first embodiment.

Next, a flexible board mounting process for mounting the flexible printed circuit board 313 on the liquid crystal panel 311 will be described. The flexible board mounting process is included in a method of manufacturing the liquid crystal panel 311. The flexible board mounting process includes at least an anisotropic conductive film applying process, a provisional pressing process, and a pressing process. In the anisotropic conductive film applying process, an anisotropic conductive film 327 is applied on the flexible board mount portion GSf of the glass substrate GS included in the array substrate 311b. In the provisional pressing process, the flexible printed circuit board 313 is placed on the anisotropic conductive film 327 and the flexible printed circuit board 313 is provisionally pressed, and fixed to the anisotropic conductive film 327 in the pressing process. In the pressing process, as illustrated in FIG. 27, the liquid crystal panel 311 is placed on the substrate support member 341 included in the flexible printed circuit board mounting apparatus 49 and is supported and stayed. In the flexible printed circuit board mounting apparatus 49 that is in the initial state, the movement control portion controls driving of a first moving portion and a second moving portion such that the substrate support member 341 is lowered in the Z-axis direction and the flexible board-side heat supply support member 51 is lowered in the Z-axis direction. Accordingly, the flexible board mount portion GSf of the glass substrate GS supported by the substrate support member 341 is relatively moved to be closer to the flexible board mount-side heat supply support member 50 and the flexible board-side heat supply support member 51 is relatively moved to be closer to the flexible printed circuit board 313.

If the flexible board mount portion GSf is in contact with the flexible board mount-side heat supply support member 50 and the flexible board-side heat supply support member 51 is in contact with the flexible printed circuit board 313, heat is supplied from the flexible board mount-side heat supply support member 50 to the flexible board mount portion GSf and heat is supplied from the flexible board-side heat supply support member 51 to the flexible printed circuit board 313. The heat supplied to the flexible board mount portion GSf and the flexible printed circuit board 313 from a contact start time is transferred to thermosetting resin 327b of the anisotropic conductive film 327 and thermal curing of the thermosetting resin 327b is accelerated. In such a contact state, the lowering of the substrate support member 341 is stopped. However, the flexible board-side heat supply support member 51 is being lowered further and therefore, the flexible printed circuit board 313 and the flexible board mount portion GSf that are sandwiched between the flexible board mount-side heat supply support member 50 and the flexible board-side heat supply support member 51, and the anisotropic conductive film 327 between the flexible printed circuit board 313 and the flexible board mount portion GSf are pressed. If the flexible board-side heat supply support member 51 reaches a certain height position, the lowering thereof is stopped and the pressing and the heat supplying are continued for a certain period. Accordingly, the terminals 13a on the flexible printed circuit board 313 side are electrically connected to the external connection terminals 322 on the flexible board mount portion GSf side via the conductive particles 327a contained in the anisotropic conductive film 327, and the thermosetting resin 327b included in the anisotropic conductive film 327 is thermally cured effectively and the flexible printed circuit board 313 is pressed and fixed to the flexible board mount portion GSf.

### Fifth Embodiment

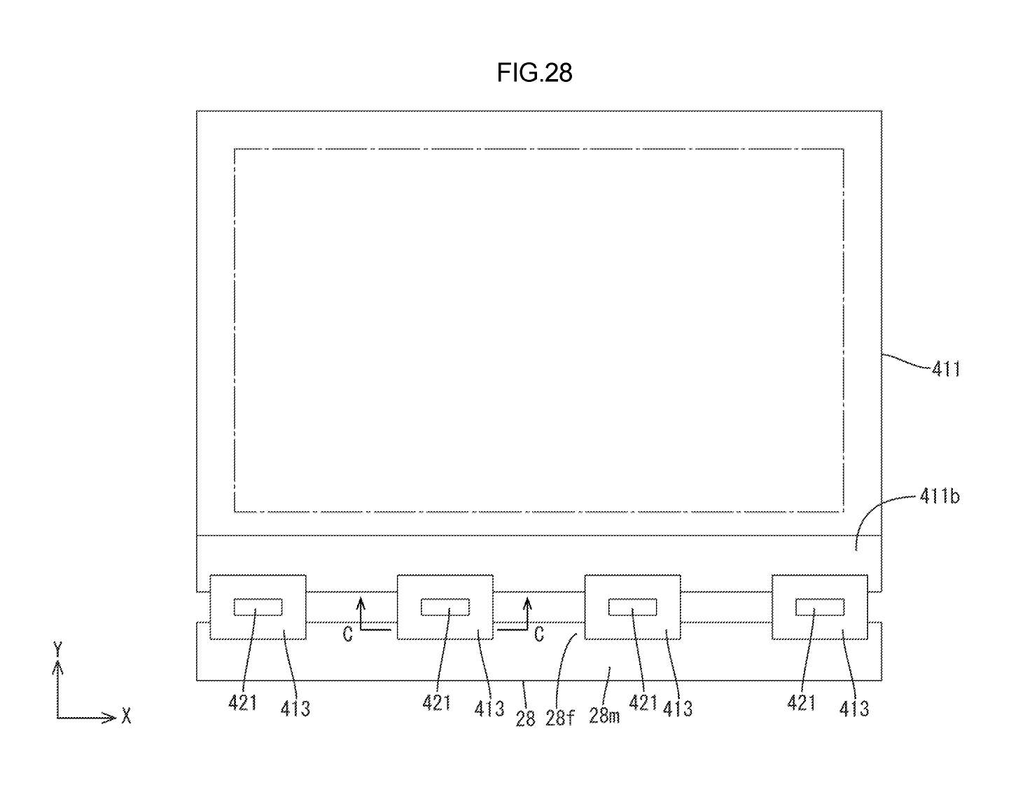

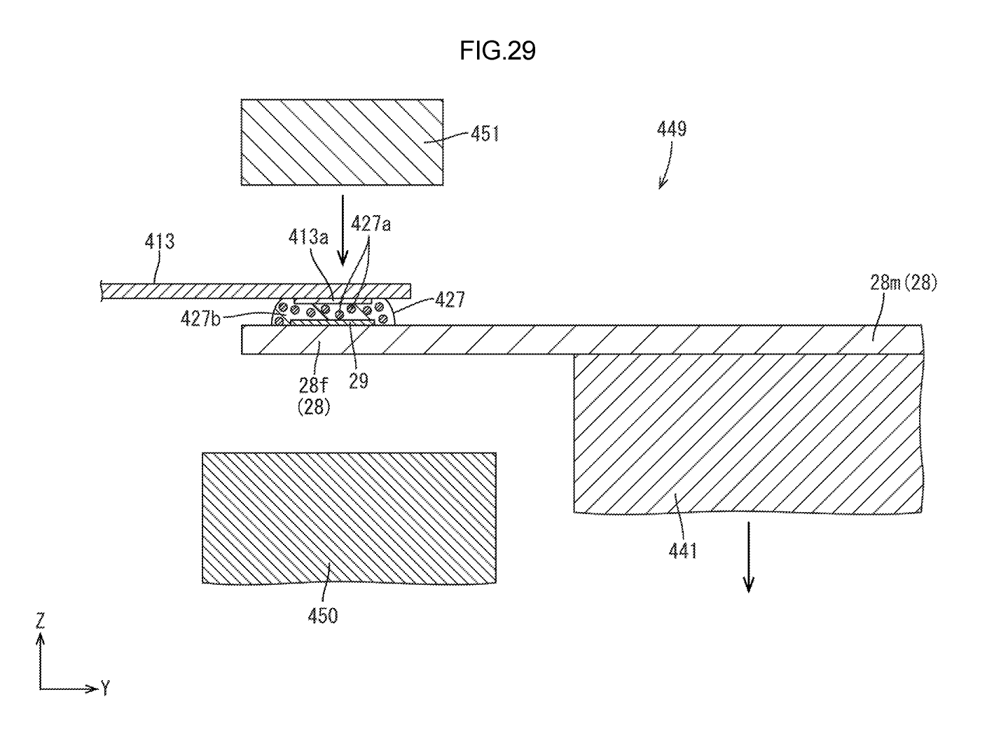

A fifth embodiment of the present invention will be described with reference to FIGS. 28 and 29. In the fifth embodiment, a configuration of a flexible printed circuit board 413 differs from that of the fourth embodiment and a flexible printed circuit board mounting apparatus 449 used for mounting the flexible printed circuit boards 413 on a printed circuit board 28 is described. Configurations, operations, and effects similar to those in the fourth embodiment will not be described.

As illustrated in FIGS. 28 and 29, the flexible printed circuit board 413 includes a film substrate and a driver 421 mounted on the film substrate and one edge portion of the substrate is mounted on an array substrate 411b of a liquid crystal panel 411 and another edge portion of the substrate is mounted on the printed circuit board (base board) 28. The flexible printed circuit board 413 includes flexible board-side terminals 413a on the other edge portion thereof. The flexible board-side terminals 413a are electrically connected to printed circuit board-side terminals 29 mounted on the printed circuit board 28 via conductive particles 427a contained in an anisotropic conductive film 427. The flexible board-side terminals 413a are arranged linearly at a predetermined interval in the X-axis direction and the printed circuit board-side terminals 29 are arranged linearly at a predetermined interval in the X-axis direction. The four flexible printed circuit boards 413 are arranged at an interval in a long-side direction of the array substrate 411b of the liquid crystal panel 411 and are connected to a long-side edge of the array substrate 411b. Accordingly, the liquid crystal panel 411 according to the present embodiment has a screen size larger than those of the embodiments 1 to 4 and has a higher resolution and therefore, multiple flexible printed circuit boards 413 are mounted.

The flexible printed circuit board mounting apparatus 449 illustrated in FIG. 29 is used in a flexible printed circuit board mounting process of mounting the flexible printed circuit board 413 on the printed circuit board 28. The flexible printed circuit board mounting apparatus 449 includes a substrate support member 441, a flexible board mount-side heat supply support member 450, and a flexible board-side heat supply support member 451. The substrate support member 441 supports a base board main portion 28m of the printed circuit board 28 from a rear side. The flexible board mount-side heat supply support member 450 supports from a rear side a flexible board mount portion (a component mount portion) 28f where the flexible printed circuit board 413 is mounted and supplies heat to the flexible board mount portion 28f. The flexible board-side heat supply support member 451 supports the flexible printed circuit board 413 from a front side and supplies heat to the flexible printed circuit board 413.

Next, a flexible board mounting process for mounting the flexible printed circuit board 413 on the printed circuit board 28 will be described. The flexible board mounting process includes at least an anisotropic conductive film applying process, a provisional pressing process, and a pressing process. In the anisotropic conductive film applying process, an anisotropic conductive film 427 is applied on the flexible board mount portion 28f of the printed circuit board 28 where the flexible printed circuit board 413 is mounted. In the provisional pressing process, the flexible printed circuit board 413 is placed on the anisotropic conductive film 427 and the flexible printed circuit board 413 is provisionally pressed, and fixed to the anisotropic conductive film 427 in the pressing process. In the pressing process, as illustrated in FIG. 29, the printed circuit board 28 is placed on the substrate support member 441 included in the flexible printed circuit board mounting apparatus 449 and is supported and stayed. In the flexible printed circuit board mounting apparatus 449 that is in the initial state, the movement control portion controls driving of a first moving portion and a second moving portion such that the substrate support member 441 is lowered in the Z-axis direction and the flexible board-side heat supply support member 451 is lowered in the Z-axis direction. Accordingly, the flexible board mount portion 28f of the printed circuit board 28 supported by the substrate support member 441 is relatively moved to be closer to the flexible board mount-side heat supply support member 450 and the flexible board-side heat supply support member 451 is relatively moved to be closer to the flexible printed circuit board 413.

If the flexible board mount portion 28f is in contact with the flexible board mount-side heat supply support member 450 and the flexible board-side heat supply support member 451 is in contact with the flexible printed circuit board 413, heat is supplied from the flexible board mount-side heat supply support member 450 to the flexible board mount portion 28f and heat is supplied from the flexible board-side heat supply support member 451 to the flexible printed circuit board 413. The heat supplied to the flexible board mount portion 28f and the flexible printed circuit board 413 from a contact start time is transferred to thermosetting resin 427b of the anisotropic conductive film 427 and thermal curing of the thermosetting resin 427b is accelerated. In such a contact state, the lowering of the substrate support member 441 is stopped. However, the flexible board-side heat supply support member 451 is being lowered further and therefore, the flexible printed circuit board 413 and the flexible board mount portion 28f that are sandwiched between the flexible board mount-side heat supply support member 450 and the flexible board-side heat supply support member 451, and the anisotropic conductive film 427 between the flexible printed circuit board 413 and the flexible board mount portion 28f are pressed. If the flexible board-side heat supply support member 451 reaches a certain height position, the lowering thereof is stopped and the pressing and the heat supplying are continued for a certain period. Accordingly, the terminals 413a on the flexible printed circuit board 413 side are electrically connected to the printed circuit board-side terminals 29 mounted on the flexible board mount portion 28f via the conductive particles 427a contained in an anisotropic conductive film 427. The thermosetting resin 427b included in the anisotropic conductive film 427 is thermally cured effectively and the flexible printed circuit board 413 is pressed and fixed to the flexible board mount portion 28f.

### Sixth Embodiment

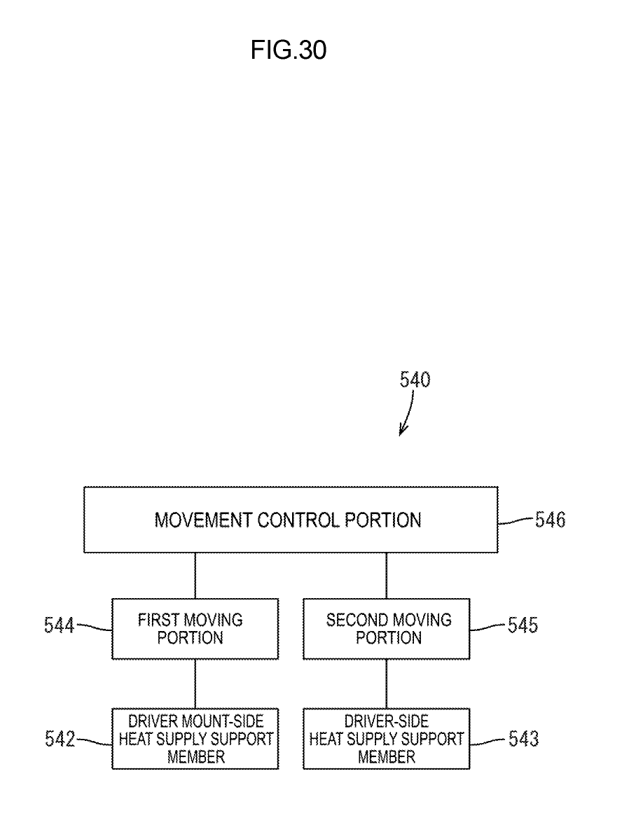

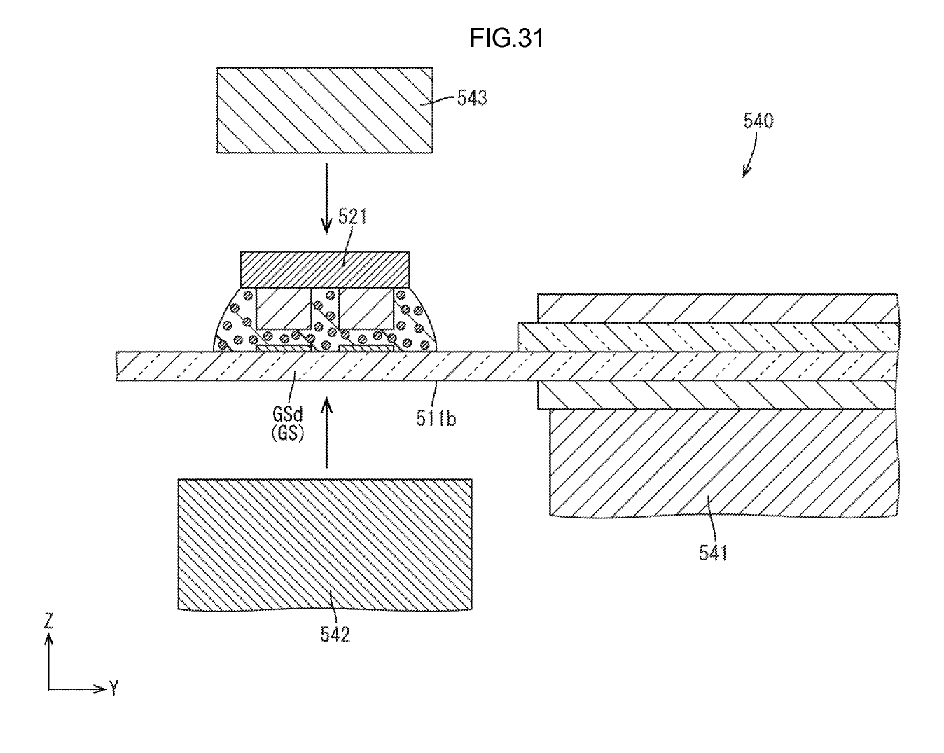

A sixth embodiment of the present invention will be described with reference to FIGS. 30 and 31. The sixth embodiment differs from the first embodiment in that a first moving portion moves a driver mount-side heat supply support member 542. Configurations, operations, and effects similar to those of the first embodiment will not be described.

As illustrated in FIGS. 30 and 31, in a driver mounting apparatus 540 according to the present embodiment, the driver mount-side heat supply support member 542 is moved by a first moving portion 544 and a position of a substrate support member 541 is fixed in the Z-axis direction. In the initial state, the driver mount-side heat supply support member 542 is away from the driver mount portion GSd of the glass substrate GS with a certain distance therebetween. The driver mount-side heat supply support member 542 is on a rear side with respect to the driver mount portion GSd of an array substrate 511b supported by the substrate support member 541 that is fixed. In mounting the driver 521, a movement control portion 546 controls the first moving portion 544 and a second moving portion 545 such that a driver-side heat supply support member 543 is lowered in the Z-axis direction to be closer to the driver 521 and the driver mount-side heat supply support member 542 is lifted up in the Z-axis direction to be closer to the driver mount portion GSd. The movement control portion 546 controls the first moving portion 544 and the second moving portion 545 such that timing of contacting the driver-side heat supply support member 543 with the driver 521 and starting heat supply and timing of contacting the driver mount-side heat supply support member 542 with the driver mount portion GSd and starting heat supply are controlled.

### Seventh Embodiment

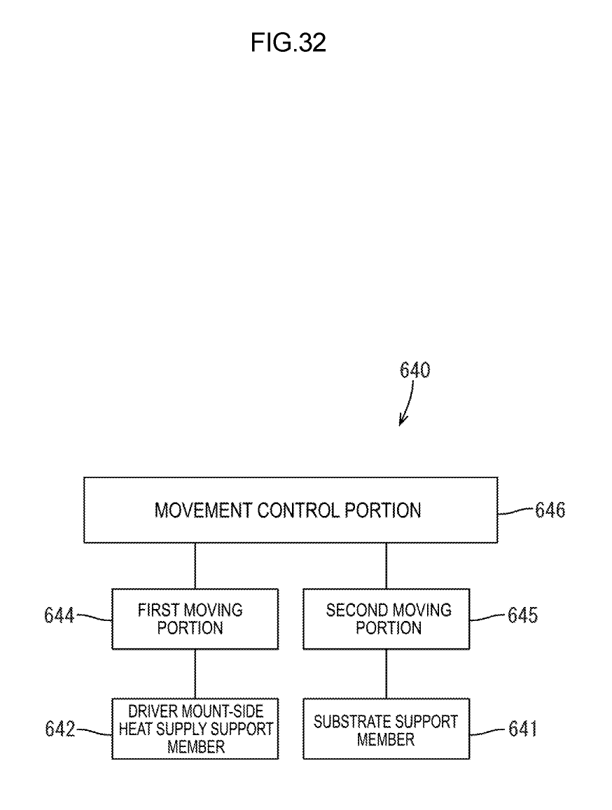

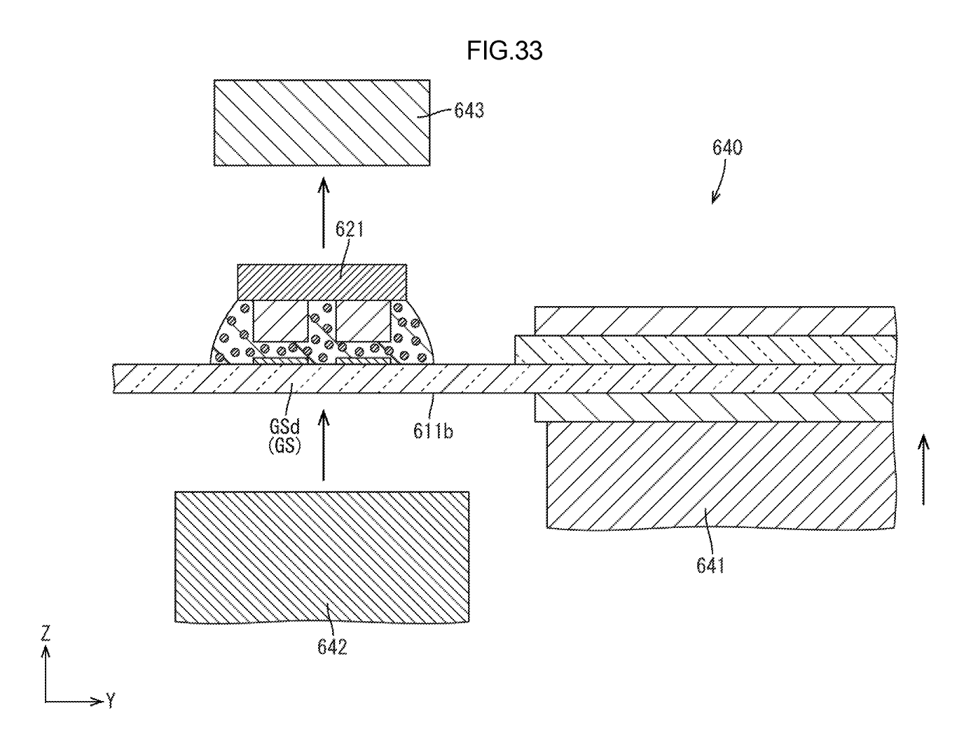

A seventh embodiment of the present invention will be described with reference to FIGS. 32 and 33. The seventh embodiment differs from the sixth embodiment in that a second moving portion 645 moves a substrate support member 641. Configurations, operations, and effects similar to those of the sixth embodiment will not be described.

As illustrated in FIGS. 32 and 33, in a driver mounting apparatus 640 according to the present embodiment, the substrate support member 641 is moved by the second moving portion 645 and a position of a driver-side heat supply support member 643 is fixed in the Z-axis direction. In the initial state, the substrate support member 641 supports the substrate main portion GSm of the glass substrate GS of an array substrate 611b and is arranged such that the driver 621 placed on the driver mount portion GSd of the supported glass substrate GS is away from the driver-side heat supply support member 643 with a certain distance therebetween. The driver 621 is on a rear side with respect to the driver-side heat supply support member 643 that is fixed. In mounting the driver 621, a movement control portion 646 controls a first moving portion 644 and the second moving portion 645 such that the substrate support member 641 is lifted up in the Z-axis direction and the driver 621 placed on the driver mount portion GSd of the supported glass substrate GS is closer to the driver-side heat supply support member 643 and the driver mount-side heat supply support member 642 is lifted up in the Z-axis direction to be closer to the driver mount portion GSd. The movement control portion 646 controls the first moving portion 644 and the second moving portion 645 such that timing of contacting the driver 621 with the driver-side heat supply support member 643 and starting heat supply and timing of contacting the driver mount-side heat supply support member 642 with the driver mount portion GSd and starting heat supply are controlled.

### Other Embodiments

The present invention is not limited to the embodiments, which have been described using the foregoing descriptions and the drawings. For example, embodiments described below are also included in the technical scope of the present invention.

(1) In each of the above embodiments, the movement control portion controls the first moving portion and the second moving portion to adjust moving speed of respective support members. For example, a position of each of the support members in the Z-axis direction, that is, a distance between the component and the mounting component-side heat supply support member (43) in the initial state or a distance between the component and the component mount-side heat supply support member (42) may be adjusted appropriately according to a thickness of the component mount portion and the moving speed of each support member may be constant.

(2) The technical matters described in (1) may be applied to each of the above embodiments.

(3) In each of the above embodiments, the position detection sensor detects a height position of the outer plate surface of the glass substrate (the printed circuit board) and the movement control portion controls the first moving portion and the second moving portion based on the detected results. For example, the thickness of the glass substrate may be measured by a measurement device and the movement control portion may control the first moving portion and the second moving portion based on the measured results.

(4) Other than each of the embodiments, relation of thickness of the component mount portion, thickness of the component, timing of contacting the mounting component-side heat supply support member with the component, and timing of contacting the component mount-side heat supply support member with the component mount portion may be altered appropriately according to a material of the substrate and the mounted member (thermal conductivity, linear expansion coefficient).

(5) In the second embodiment, time elapsed after the contact of the a component mount-side heat supply support member with the driver mount portion is obtained by the timer and the load sensor and the driver-side heat supply support member is moved based on the elapsed time. Instead of the timer and the load sensor, for example, a thermometer for measuring temperature of the driver mount portion is provided and the driver-side heat supply support member may be moved when temperature measured by the thermometer reaches a set temperature.

(6) In each of the above embodiments, among the substrate support member, the component mount-side heat supply support member, and the mounting component-side heat supply support member, one is fixed and other two are arranged movable. All of the substrate support member, the component mount-side heat supply support member, and the mounting component-side heat supply support member may be arranged movable. In such a configuration, a third moving portion may be further included in addition to the first moving portion and the second moving portion. The third moving portion may relatively move the component mount portion and the component mount-side heat supply support member in the overlapping direction or relatively move the component and the mounting component-side heat supply support member.

(7) In each of the above embodiments, a buffer may be disposed between the component and the mounting component-side heat supply support member.

(8) Other than the fifth embodiment, the number and the arrangement of the flexible printed circuit board connected to the liquid crystal panel may be altered, if necessary.

(9) In the fifth embodiment, the flexible printed circuit board mounting apparatus used in mounting the flexible printed circuit board having the driver on the printed circuit board is described. In mounting the flexible printed circuit board having the driver on the liquid crystal panel, the flexible printed circuit board mounting apparatus according to the fourth embodiment may be used.

(10) In each of the above embodiments, an elongated driver is used as the component. For example, a driver having a square plan-view shape may be used as the component.

(11) Each of the above embodiments describes a manufacturing apparatus for mounting the driver and the flexible printed circuit board on the array substrate included in a transmissive liquid crystal display device including a backlight device as an external light source and a manufacturing method with using the apparatus. The present invention may be applied to a manufacturing apparatus for mounting the driver and the flexible printed circuit board on the array substrate included in a reflective liquid crystal display device using external light and a manufacturing method with using the apparatus.

(12) In each of the embodiments, the TFTs are used as switching components of the liquid crystal display device. However, a manufacturing apparatus for mounting the driver and the flexible printed circuit board on the array substrate included in liquid crystal display devices that include switching components other than TFTs (e.g., thin film diodes (TFDs)) and a manufacturing method with using the apparatus may be included in the scope of the present invention. Furthermore, a manufacturing apparatus for mounting the driver and the flexible printed circuit board on the array substrate included in black-and-white liquid crystal display devices, other than color liquid crystal display device, and a manufacturing method with using the apparatus are also included in the scope of the present invention.

(13) The manufacturing apparatus for mounting the driver and the flexible printed circuit board on the array substrate included in liquid crystal display devices including the liquid crystal panels as the display panels and a manufacturing method with using the apparatus are described as the embodiments. However, a manufacturing apparatus for mounting the driver and the flexible printed circuit board on the array substrate included in display devices that include other types of display panels (e.g., plasma display panels (PDPs) and organic EL panels) and a manufacturing method with using the apparatus are also included in the scope of the present invention.

### EXPLANATION OF SYMBOLS

11b, 311b, 411b: array substrate (mounting substrate), 13b: substrate (base board), 21, 121, 221, 421: driver (component), 28: printed circuit board (base board), 28f: flexible board mount portion (component mount portion), 28m: substrate main portion, 40, 140, 540, 640: driver mounting apparatus (manufacturing apparatus), 41, 141, 241, 341, 441, 541, 641: substrate support member, 42, 142, 242, 542, 642: driver mount-side heat supply support member (component mount-side heat supply support member), 43, 143, 243, 543, 643: driver-side heat supply support member (component-side heat supply support member), 44, 144, 544, 645: first moving portion, 45, 145, 545, 645: second moving portion, 46: 146, 546, 646: movement control portion, 47: timer, 49, 449: flexible printed circuit board mounting apparatus (manufacturing apparatus), 50, 450: flexible board mount-side heat supply support member (component mount-side heat supply support member), 51, 451: flexible board-side heat supply support member (component-side heat supply support member), 313, 413; flexible printed circuit board (component), 813: flexible mounted circuit board (component), GS: glass substrate (base board), GSd: driver mount portion (component mount portion), GSf: flexible board mount portion (component mount portion), GSm: substrate main portion

1. A mounting substrate manufacturing apparatus comprising:
a component mount-side heat supply support member arranged on an opposite side from a component with respect to a substrate where the component is to be mounted, the component mount-side heat supply support member supporting a component mount portion of the substrate where the component is to be mounted and supplying heat to the component mount portion;
a substrate support member arranged on a same side with the component mount-side heat supply support member with respect to the substrate and supporting a substrate main portion of the substrate except for the component mount portion;
a component-side heat supply support member arranged on an opposite side from the component mount portion with respect to the component, the component-side heat supply support member sandwiching and supporting the component with the component mount-side heat supply support member supporting the component mount portion and supplies heat to the component;
a first moving portion that relatively moves the component mount portion and the component mount-side heat supply support member in an overlapping direction in which the substrate and the component are overlapped; and
a second moving portion that relatively moves the component and the component-side heat supply support member in the overlapping direction.

2. The mounting substrate manufacturing apparatus according to claim 1, further comprising:
a movement control portion configured to control the first moving portion and the second moving portion to adjust relative moving speed of the component mount portion and the component mount-side heat supply support member and relative moving speed of the component and the component-side heat supply support member, respectively.

3. The mounting substrate manufacturing apparatus according to claim 2, wherein
the movement control portion configured to control the first moving portion and the second moving portion such that timing of contacting the component mount-side heat supply support member with the component mount portion and timing of contacting the component-side heat supply support member with the component are same.

4. The mounting substrate manufacturing apparatus according to claim 2, wherein
the movement control portion configured to control the first moving portion and the second moving portion such that timing of contacting the component mount-side heat supply support member with the component mount portion is prior to timing of contacting the component-side heat supply support member with the component.

5. The mounting substrate manufacturing apparatus according to claim 4, further comprising a timer counting time that has passed after the component mount-side heat supply support member is in contact with the component mount portion, wherein
the movement control portion is configured to control the second moving portion to start relative movement of the component and the component-side heat supply support member to be closer to each other, if counted time counted by the timer reaches predetermined time.

6. The mounting substrate manufacturing apparatus according to claim 2, wherein
the movement control portion configured to control the first moving portion and the second moving portion such that timing of contacting the component mount-side heat supply support member with the component mount portion is after timing of contacting the component-side heat supply support member with the component.

7. The mounting substrate manufacturing apparatus according to claim 2, wherein
the movement control portion configured to control the first moving portion and the second moving portion such that relative moving speed of the component mount portion and the component mount-side heat supply support member and relative moving speed of the component and the component-side heat supply support member change during moving.

8. The mounting substrate manufacturing apparatus according to claim 1, wherein
the component mount-side heat supply support member is fixed with respect to the overlapping direction,
the first moving portion is configured to move the substrate support member such that the component mount portion of the substrate supported by the substrate support member is relatively moved with respect to the component mount-side heat supply support member, and
the second moving portion is configured to move the component-side heat supply support member such that the component-side heat supply support member is relatively moved with respect to the component.

9. A method of manufacturing a mounting substrate comprising:
a provisional pressing process in which a component is provisionally pressed and fixed on a substrate; and
a pressing process in which
a substrate main portion of the substrate except for a component mount portion where the component is to be mounted is supported by a substrate support member arranged on an opposite side from the component with respect to the substrate where the component is to be mounted,
a component mount-side heat supply support member and a component mount portion that are arranged on a same side with the substrate support member with respect to the substrate are relatively moved by a first moving portion in an overlapping direction in which the substrate and the component are overlapped,
a component-side heat supply support member and the component that are arranged on an opposite side from the component mount-side supply support member with respect to the substrate are relatively moved by a second moving portion in the overlapping direction,
the component mount portion is in contact with and supported by the component mount-side heat supply support member and heat is supplied to the component mount portion from the component mount-side heat supply support member, and
the component is in contact with and supported by the component-side heat supply support member and heat is supplied to the component from the component-side heat supply support member, whereby the component is pressed and fixed on the substrate.

10. The method of manufacturing a mounting substrate according to claim 9, wherein
in the pressing process, a movement control portion controls the first moving portion and the second moving portion to adjust relative moving speed of the component mount portion and the component mount-side heat supply support member and adjust relative moving speed of the component and the component-side heat supply support member, respectively.

11. The mounting substrate manufacturing apparatus according to claim 10, wherein
in the pressing process, the movement control portion controls the first moving portion and the second moving portion such that timing of contacting the component mount-side heat supply support member with the component mount portion and timing of contacting the component-side heat supply support member with the component are same.

12. The mounting substrate manufacturing apparatus according to claim 10, wherein
in the pressing process, the movement control portion controls the first moving portion and the second moving portion such that timing of contacting the component mount-side heat supply support member with the component mount portion is prior to timing of contacting the component-side heat supply support member with the component.

13. The mounting substrate manufacturing apparatus according to claim 10, wherein
in the pressing process, the movement control portion controls the first moving portion and the second moving portion such that timing of contacting the component mount-side heat supply support member with the component mount portion is after timing of contacting the component-side heat supply support member with the component.
